(19) United States
(12) Patent Application Publication
(10) Pub. No.: US 2015/0076578 A1
(43) Pub. Date: Mar. 19, 2015

(54) NONVOLATILE SEMICONDUCTOR STORAGE DEVICE

(71) Applicant: KABUSHIKI KAISHA TOSHIBA, Minato-ku (JP)

(72) Inventors: Wataru SAKAMOTO, Yokkaichi (JP); Kenta YAMADA, Yokkaichi (JP)

(73) Assignee: KABUSHIKI KAISHA TOSHIBA, Minato-ku (JP)

(21) Appl. No.: 14/291,816

(22) Filed: May 30, 2014

(30) Foreign Application Priority Data
Sep. 17, 2013 (JP) 2013-192059

(51) Int. Cl. H01L 27/115

(52) U.S. Cl. CPC H01L 27/11529; H01L 27/11551; H01L 27/11573; H01L 27/11578
USPC 257/300

(57) ABSTRACT

A nonvolatile semiconductor storage device is provided with a memory-cell region; a peripheral-circuit region disposed adjacent to the memory-cell region a first memory-cell unit disposed in a first layer located in the memory-cell region; a second memory-cell unit disposed in a k-th layer of the memory-cell region where k is an integer equal to or greater than 2, the second memory-cell unit having an element region extending in a first direction and having a first width in a second direction crossing the first direction; and a peripheral-circuit element disposed in the first layer located in the peripheral-circuit region. Two or more dummy element each having a second width 2n+1 times greater than the first width in the second direction are disposed in the k-th layer located in the peripheral-circuit region where n is an integer equal to or greater than 0.

### CROSS-REFERENCE TO RELATED APPLICATION(S)

This application is based upon and claims the benefit of priority from Japanese Patent Application No. 2013-192059, filed on, Sep. 17, 2013 the entire contents of which are incorporated herein by reference.

### FIELD

Embodiments disclosed herein generally relate to a nonvolatile semiconductor storage device.

### BACKGROUND

Nonvolatile semiconductor storage devices are used in various equipment. A nonvolatile semiconductor device is provided with cell units. In recent years, three-dimensional cell units, depletion-type memory cells, or the like are being considered due to advances in shrinking and integration of semiconductor elements.

### BRIEF DESCRIPTION OF THE DRAWINGS

FIG. 1 is one example of a block diagram schematically and partially illustrating an electrical configuration of a nonvolatile semiconductor storage device of a first embodiment.

FIG. 2A is one schematic example of a planar layout of some of the structures of memory-cell region provided in the nonvolatile semiconductor storage device of the first embodiment.

FIG. 2B is one schematic example of a planar layout of peripheral circuit elements of peripheral-circuit region provided in the nonvolatile semiconductor storage device of the first embodiment.

FIG. 2C is one example of a plan view illustrating how the memory-cell region and the peripheral-circuit region are located with respect to one another in the nonvolatile semiconductor storage device of the first embodiment.

FIG. 3 is one example of a vertical cross-sectional view taken along line A-A of FIG. 2A and schematically illustrates the structures in the memory-cell region of the first embodiment.

FIG. 4 is one example of a vertical cross-sectional view taken along line B-B of FIG. 2C and schematically illustrates the structures in the memory-cell region, the peripheral-circuit region, and the boundary region between the foregoing regions of the first embodiment.

FIGS. 5 to 10 are examples of vertical cross-sectional views schematically illustrating one phase of the manufacturing process flow of the structures of the first embodiment.

FIG. 11 is one example of a vertical cross-sectional view taken along line B-B of FIG. 2C and schematically illustrates the structures in the memory-cell region, the peripheral-circuit region, and the boundary region between the foregoing regions of a second embodiment.

FIGS. 12 to 21 are examples of vertical cross-sectional views schematically illustrating one phase of the manufacturing process flow of the structures of the second embodiment.

FIG. 22 is one example of a vertical cross-sectional view taken along line B-B of FIG. 2C and schematically illustrates the structures in the memory-cell region, the peripheral-circuit region, and the boundary region between the foregoing regions of a third embodiment.

FIGS. 23 to 41 are examples of vertical cross-sectional views schematically illustrating one phase of the manufacturing process flow of the structures of the third embodiment.

FIG. 42 is one schematic example of a plan view schematically illustrating the structures of resistive elements of a fourth embodiment.

FIG. 43 is one example of a vertical cross-sectional view taken along line C-C of FIG. 42 of a fourth embodiment.

FIG. 44 is an example of a plan view schematically illustrating one phase of the manufacturing process flow of the structures of the fourth embodiment.

FIGS. 45, 46B, and 47B are examples of vertical cross-sectional views schematically illustrating one phase of the manufacturing process flow of the structures of the fourth embodiment.

FIGS. 46A and 47A are examples of plan views schematically illustrating one phase of the manufacturing process flow of the structures of the fourth embodiment.

FIG. 48 is one schematic example of a plan view schematically illustrating the structures of capacitive elements of a fourth embodiment.

FIG. 49 is one example of a vertical cross-sectional view taken along line D-D of FIG. 48 of the fourth embodiment.

FIG. 50A is one example of a vertical cross-sectional view taken along line E-E of FIG. 48 of the fourth embodiment.

FIG. 50B is one example of plan view schematically illustrating one phase of the manufacturing process flow of the structures of the fourth embodiment.

FIG. 51 is one example of plan view schematically illustrating the relation between the structures of the first layer and the second layer of a fifth embodiment.

FIG. 52 is one example of a vertical cross-sectional view taken along line F-F of FIG. 51 of the fifth embodiment.

FIG. 53 is one example of a vertical cross-sectional view taken along line J-J of FIG. 51 of the fifth embodiment.

FIGS. 54 to 56 are examples of vertical cross-sectional views schematically illustrating one phase of the manufacturing process flow of the structures of the fifth embodiment.

FIG. 57 is one example of plan view schematically illustrating the relation between the structures of the first layer and the second layer of a sixth embodiment.

FIG. 58 is one example of a vertical cross-sectional view taken along line H-H of FIG. 57 of the sixth embodiment.

FIGS. 59 to 60 are examples of plan views schematically illustrating one phase of the manufacturing process flow of the structures of the sixth embodiment.

FIG. 61 is one example of a descriptive view for explaining the operation of a depletion mode when steps are not formed in the upper portions of a semiconductor substrate of a seventh embodiment.

FIG. 62 is one example of a descriptive view for explaining the operation of an accumulation mode when steps are not formed in the upper portions of the semiconductor substrate of the seventh embodiment.

FIG. 63 is one example of a descriptive view for explaining the operation in a structure in which the depletion mode and the accumulation mode coincide when steps are not formed in the upper portions of the semiconductor substrate of the seventh embodiment.

FIG. 64 is one example of a vertical cross-sectional view schematically illustrating the structures of a memory-cell unit of the seventh embodiment.

FIG. 65 is one example of a vertical cross-sectional view schematically illustrating the structures of some of the memory-cell transistors of the seventh embodiment.

FIGS. 66 to 69 are examples of descriptive views for explaining the operation of the structures of the seventh embodiment.

FIGS. 70 to 72 are examples of vertical cross-sectional views schematically illustrating one phase of the manufacturing process flow of the structures of the seventh embodiment.

FIG. 73 is one example of a vertical cross-sectional view schematically illustrating the structures of a modified embodiment of the seventh embodiment.

FIG. 74 is one example of a vertical cross-sectional view schematically illustrating the structures of a memory-cell unit of an eighth embodiment.

FIG. 75 is one example of a vertical cross-sectional view schematically illustrating the structures of some of the memory-cell transistors of the eighth embodiment.

FIG. 76 is one example of a vertical cross-sectional view schematically illustrating the structures of a memory-cell unit of a ninth embodiment.

### DETAILED DESCRIPTION

In one embodiment, a nonvolatile semiconductor storage device is provided with a memory-cell region; a peripheral-circuit region disposed adjacent to the memory-cell region a first memory-cell unit disposed in a first layer located in the memory-cell region; a second memory-cell unit disposed in a k-th layer of the memory-cell region where k is an integer equal to or greater than 2, the second memory-cell unit having an element region extending in a first direction and having a first width in a second direction crossing the first direction; and a peripheral-circuit element disposed in the first layer located in the peripheral-circuit region. Two or more dummy elements each having a second width 2n+1 times greater than the first width in the second direction are disposed in the k-th layer located in the peripheral-circuit region where n is an integer equal to or greater than 0.

In one embodiment, a nonvolatile semiconductor storage device is provided with a memory-cell region; a peripheral-circuit region disposed adjacent to the memory-cell region; a first memory-cell unit disposed in a first layer located in the memory-cell region; a second memory-cell unit disposed in a k-th layer located in the memory-cell region where k is an integer equal to or greater than 2, the second memory-cell unit having an element region extending in a first direction and having a first width in a second direction crossing the first direction; peripheral-circuit elements disposed in the first layer located in the peripheral-circuit region; dummy elements disposed in the k-th layer located in the peripheral-circuit region so as to extend in the first direction and be spaced from one another by a second width in the second direction; and contacts contacting the dummy elements via insulating films and extending, in a direction in which layers are stacked, to reach the peripheral-circuit elements in the first layer.

In one embodiment, a nonvolatile semiconductor storage device is provided with a semiconductor substrate; an element region disposed along a first direction; negative type impurity doped layer formed continuously in an upper portion of the element region; memory-cell gate electrodes disposed above the continuous n type impurity doped layers, the memory-cell gate electrodes being spaced from one another in the first direction; and trenches disposed in both sides of the memory-cell gate electrodes so as to be located in the upper portion of the negative type impurity doped layer of the element region.

Embodiments a nonvolatile semiconductor storage device and its manufacturing method are described hereinafter with references to the accompanying drawings. Elements that are identical or similar across the embodiments are identified with identical or similar reference symbols. Further, directional terms such as up, upper, upward, down, lower, downward, left, leftward, right, and rightward and relative terms such as high, low, deep, and shallow are used in a relative context with respect to a back side of a later described semiconductor substrate.

### First Embodiment

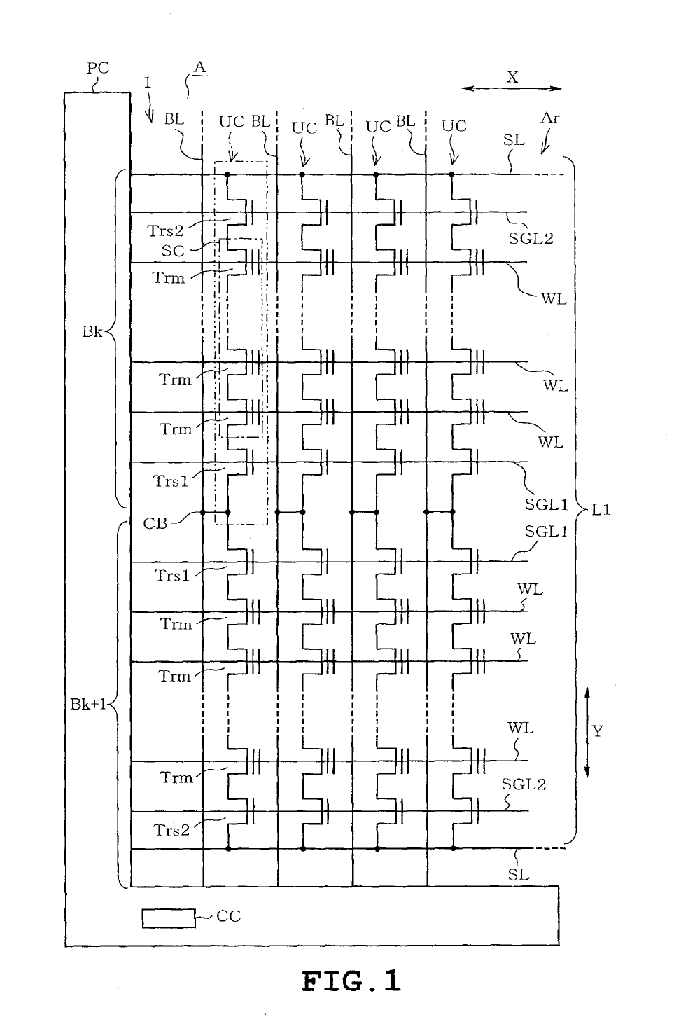

A first embodiment of a nonvolatile semiconductor storage device is described hereinafter through a NAND flash memory device application with references to FIG. 1 to FIG. 10.

FIG. 1 is one example of a schematic diagram illustrating an electrical configuration of a NAND flash memory device. As illustrated in FIG. 1, NAND flash memory device A is provided with memory-cell array Ar configured by memory-cell units UC arranged in a matrix and peripheral circuit PC that drives memory-cell array Ar.

Peripheral circuit PC is provided in peripheral-circuit region P. Peripheral circuit PC includes a row decoder for applying voltages to each of blocks Bk in memory-cell array Ar, sense amplifier or the like for detecting current, a logical circuit for processing incoming signals, power-source capacitive elements, and the like, neither of which are illustrated. The structures of peripheral-circuit P will not be described in detail. Descriptions given herein will focus on peripheral-circuit elements such as peripheral transistors Trp, capacitive elements Ca, and resistive elements Ra. For ease of explanation, peripheral circuit PC is defined as control circuit CC in whole or in part.

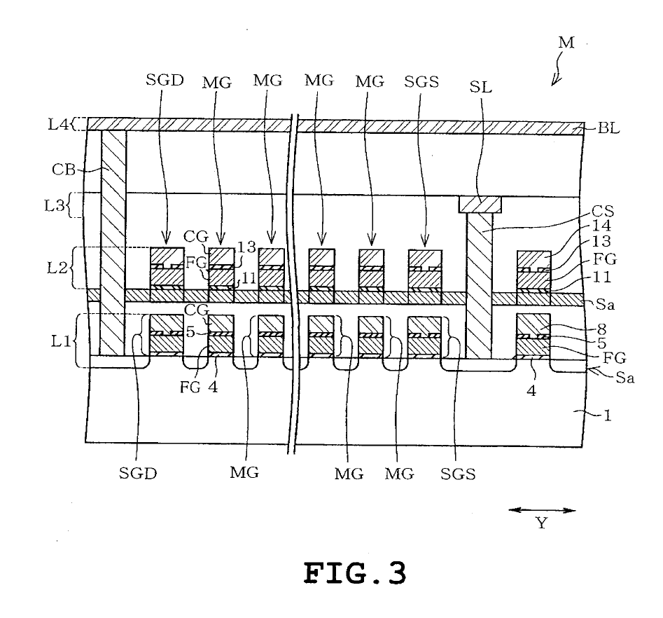

Memory-cell array Ar is provided in memory-cell region M. FIG. 1 illustrates the electrical configuration of first layer L1 formed in semiconductor substrate 1 but does not illustrate the electrical configuration of second layer L2. The electrical configuration of second layer L2 is illustrated in the later described FIG. 3. Memory-cell array Ar adopts the so-called stacked-memory-cell array structure and the electrical configuration of first layer L1 and the electrical configuration of second layer L2 are substantially the same. Thus, a description will be given hereinunder on the electrical configuration of first layer L1 but the electrical configuration of second layer L2 will not be described. In the first embodiment, the stacked structures of memory-cell array Ar of memory-cell region M is configured as a double layer for example. However, the stacked structures of memory-cell array Ar of memory-cell region M may be configured as a triple or more layer.

Memory-cell array Ar is configured by cell units UC disposed in the X direction. FIG. 1 only illustrates 2 blocks, namely block Bk and Block Bk+1 of first layer L1 for simplicity. However, there may be more than 2 blocks disposed in the Y direction (bit line direction) with each block being provided with a group of cell units UC.

Each cell unit UC is provided with select transistors Trs1 and Trs2 and memory-cell transistors Trm (64 transistors for example) series connected between select transistors Trs1 and Trs2. Memory-cell transistors Trm series connected between select transistors Trs1 and Trs2 constitute cell string SC.

In each cell unit UC, either the source or the drain of select transistor Trs1 is connected to bit line BL and the remaining other of the source or the drain of select transistor Trs1 is connected to one side of cell string SC. Either of the source or drain of select transistor Trs2 is connected to the other side of cell string SC, and the remaining other of the source or the drain of select transistor Trs2 is connected to source line SL.

A dummy transistor may be provided between select transistor Trs1 and memory-cell transistor Trm and a dummy transistor may be provided between select transistor Trs2 and memory-cell transistor Trm.

In FIG. 1, gate electrodes MG (see FIG. 3) of memory-cell transistors Trm of memory cell units UC disposed in the X direction are connected by common word lines WL. Further, select gate electrodes SGD (see FIG. 3) of select transistors Trs1 disposed in the X direction in FIG. 1 are connected by common select gate lines SGL1. Select gate electrodes SGS (see FIG. 3) of select transistors Trs2 disposed in the X direction in FIG. 1 are connected by common select gate lines SGL2. Bit-line contacts CB are provided in the drain regions of select transistors Trs1 and source-line contacts CS are provided in the source regions of select transistors Trs2.

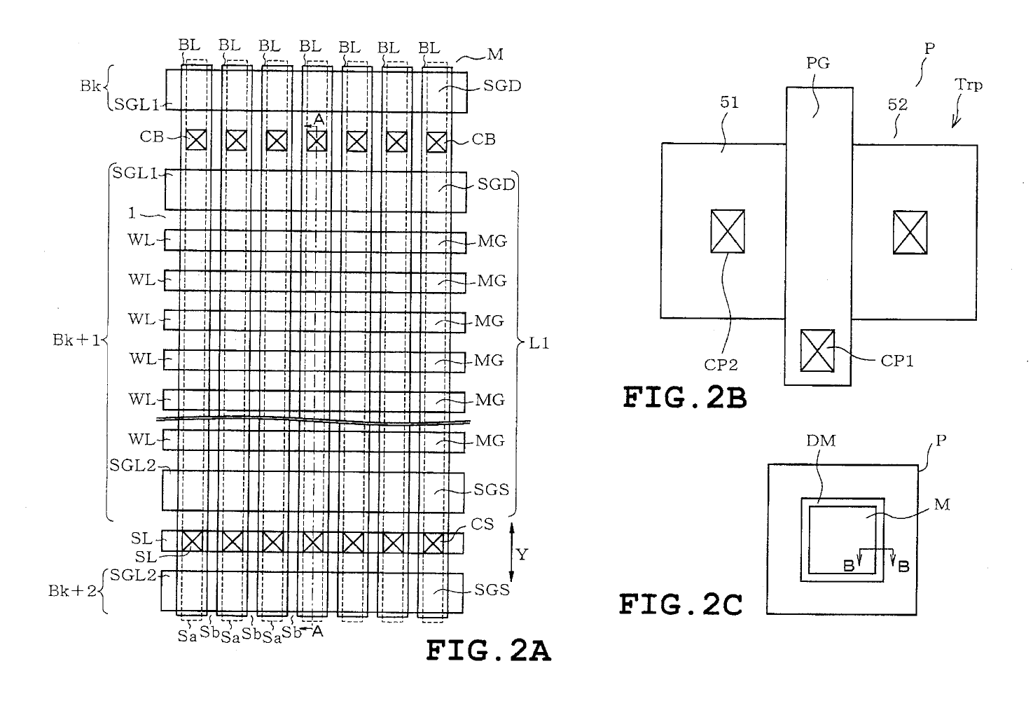

FIG. 2A is one example of a plan view schematically illustrating the layout of some of the blocks of the first layer of memory-cell region M. The layout of the blocks of second layer L2 is substantially the same as the layout of the blocks of first layer L2.

Each of cell units UC of block Bk (k≧1) is symmetrical in the Y direction to cell unit UC of the adjacent block Bk with respect to each of bit-line contacts CB. For example, in FIG. 2A, select gate line SGL1 of block Bk faces select gate line SGL1 of block Bk+1 with bit-line contacts CB disposed therebetween.

Further, each of cell units UC of block Bk is symmetrical in the Y direction to cell unit UC of the adjacent block Bk with respect to each of source-line contacts CS. Select gate line SGL2 of block Bk faces select gate line SGL2 of block Bk+1 with source-line contacts CS disposed therebetween.

A silicon substrate for example is used as semiconductor substrate 1 and element isolation regions Sb taking an STI (Shallow Trench Isolation) structure is formed in semiconductor substrate 1 so as to extend along the Y direction as viewed in FIG. 2A. Element region Sa of each cell unit UC is isolated from one another in the X direction as viewed in FIG. 2A by element isolation regions Sb.

As a result, each of element regions Sa extends in the Y direction and is isolated from one another in the X direction. The X-direction widths of element regions Sa are equal and X-direction spaces between element regions Sa are equal. Each bit-line contact CB is formed so as to contact element region Sa of each cell unit UC. Further, each source-line contact CS is formed so as to contact element region Sa of each cell unit UC.

First layer L1 including cell units UC is structured as described above. As illustrated in FIG. 3, in the first embodiment, the cell unit UC structure of first layer L1 is also formed in second layer L2 via an interlayer insulating film (not illustrated in FIG. 3) in a three-dimensional manner. Source lines SL and bit lines BL are formed above the stacked memory-cell array structure formed of first layer L1 and second layer L2.

As illustrated in FIG. 2A, bit lines BL extend in the Y direction as viewed in FIG. 2A and are spaced from one another in the X direction. The bit lines BL are formed at equal width in the X direction and are spaced from one another at equal distance in the X direction. Source lines SL, on the other hand, are formed along the X direction so as to extend over source-line contacts CS of cell units UC.

FIG. 2B schematically illustrates one example of a structure of peripheral transistors Trp formed in first layer L1 of peripheral-circuit region P. Peripheral transistors Trp for example are formed in peripheral-circuit region P. Different types of peripheral transistors Trp may be formed such as high-breakdown-voltage or low-breakdown-voltage type transistors. Peripheral transistor Trp is provided with a rectangular element region 51 and gate electrode PG extending across a central portion of element region 51.

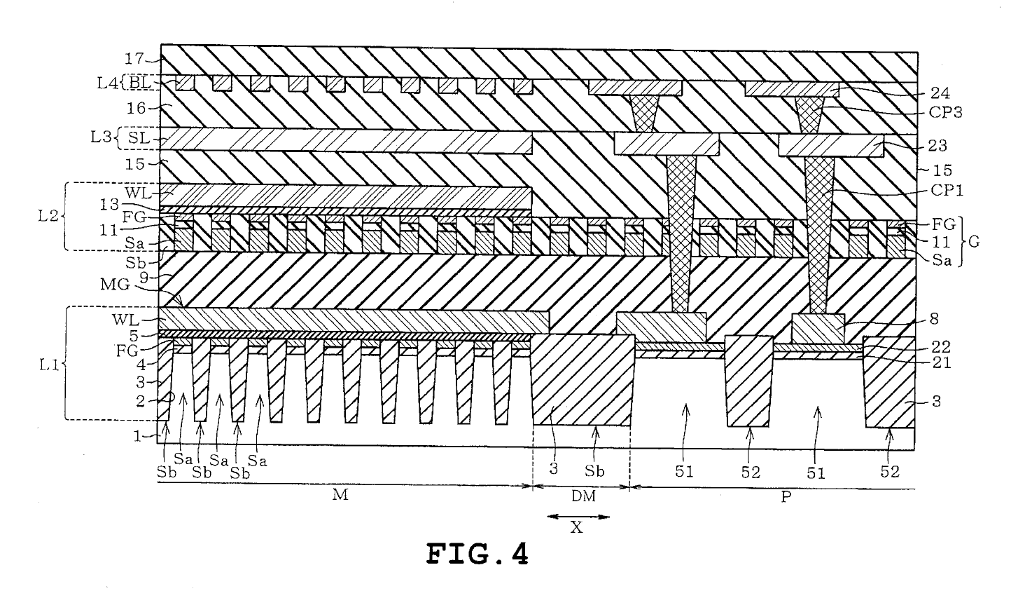

Element region 51 is surrounded by element isolation region 52 which is filled with an insulating film. Contact CP1 is formed above a portion of gate electrode PG projecting outward from element region 51. Gate electrode PG is connected to the wirings in the upper layers (see reference symbols 23 and 24 of later described FIG. 4) via contact CP1. Further, contacts CP2 for connecting to source/drain are formed above element region 51 in both sides of gate electrode PG.

FIG. 2C schematically illustrates one example of a layout of memory-cell region M and peripheral-circuit region P. As illustrated in FIG. 2C, memory-cell region M is surrounded by peripheral-circuit region P. The design rules differ significantly in the elements formed in memory-cell region M and the elements formed in peripheral-circuit region P. For process design reasons, dummy region DM illustrated in FIG. 4 may be provided as a buffer between the regions in which different design rules are applied. Either the design rule of region P or the design rule of region M may be applied to dummy region DM. Alternatively, a design rule in between the two design rules may be applied to the line width and space width of region P and region M, respectively. The elements formed in dummy region DM may not be electrically functional.

A description is given hereinunder on the cross-sectional structures of first layer L1 and second layer L2 and above in memory-cell region M of the first embodiment. FIG. 3 schematically illustrates one example of a cross-sectional structure of memory-cell region M taken along line A-A of FIG. 2A. FIG. 4 schematically illustrates one example of a cross-sectional structure of memory-cell region M, peripheral-circuit region P, and dummy region DM located between the foregoing regions taken along line B-B of FIG. 2C.

A brief description will be given on the structure of memory-cell transistor Trm with reference to FIGS. 3 and 4. Referring first to FIG. 4, a P type mono-crystalline silicon substrate is used for example as semiconductor substrate 1. Element isolation trenches 2 are formed into semiconductor substrate 1. Element isolation trenches 2 are formed along the Y direction and are separated from one another in the X direction. Element isolation trenches 2 isolate element regions Sa in the X direction. Element isolation trenches 2 are filled with element isolation films 3 to form element isolation regions Sb taking a shallow trench isolation (STI) structure.

Tunnel insulating films 4 are formed above element regions Sa isolated by element isolation regions Sb. Gate electrodes MG are formed above tunnel insulating films 4. Gate electrode MG is provided with charge-storing layer FG, IPD (interpoly dielectric) film (interelectrode insulating film) 5 formed above charge-storing layer FG, and control electrode CG formed above IPD film 5.

Tunnel insulating films 4 are formed in element regions Sa of silicon substrate 1. Tunnel insulating film 4 may be formed of for example a silicon oxide film. Charge-storing layer FG is formed of conductive layer 22. For example, conductive layer 22 may be formed of a polysilicon film doped with impurities such as phosphorous or boron and a charge trap film not illustrated disposed above the polysilicon film. The charge trap film may be formed of materials such as a silicon nitride (SiN) or a hafnium oxide (HfO). The charge trap film is provided when required. For example, the charge trap film may be provided when the polysilicon film is thin.

IPD film 5 is formed along the upper surfaces of element isolation films 3 and the upper surfaces of charge storing layers FG and may also be referred to as an interelectrode insulating film or an inter-conductive-layer insulating film. A monolayer of a high-dielectric-constant film (such as an oxide film including for example a nitride (N), hafnium (Hf), aluminum (Al), or the like) may be used as IPD film 5. Further, a silicon oxide film (SiO₂) may be used as IPD film 5. Still further, a composite film formed of the foregoing materials may be used as IPD film 5.

As illustrated in FIGS. 3 and 4, control electrodes CG serve as word lines WL of memory-cell transistors Trm and are formed of conductive layers 8. Conductive layer 8 is formed of for example: a metal layer such as a tungsten layer, or a polycrystalline silicon doped with impurities such as phosphorous, a silicide layer, or composite layers of the foregoing layers. Interlayer insulating film or the like is formed above the upper surfaces of conductive layers 8. The interlayer insulating film may be formed of for example a silicon nitride (SiN), a silicon oxide (SiO₂), or the like. Further, as illustrated in FIG. 3, gate electrodes MG of memory-cell transistors Trm are disposed in the Y direction. Select gate electrode SGD of select transistor Trs1 is disposed in one side of the group of gate electrodes MG so as to be spaced apart from gate electrodes MG.

Further, select gate electrode SGS of select transistor Trs2 is disposed on the other side of the group of gate electrodes MG so as to be spaced apart from gate electrodes MG. Trenches (not represented by reference symbols) for electrode isolation are formed between gate electrodes MG, between gate electrodes MG and SGD, and between gate electrodes MG and SGS so as to electrically isolate one another. The trenches may be filled with interlayer insulating film 9 (see FIG. 4) including a silicon oxide film formed by using for example TEOS (tetraethoxysilane). Further, gaps may be provided between gate electrodes MG to inhibit interference between gate electrodes MG.

The stacked structures of select gate electrodes SGD and SGS are substantially the same as the stacked structures of gate electrodes MG of memory-cell transistors Trm. Trenches are formed in IPD films 5 of select gate electrodes SGD and SGS. As a result, charge storing layers FG contact conductive layers 8.

As illustrated in FIGS. 3 and 4, the structures of cell units UC of second layer L2 are similar to the structures of cell units UC of first layer L1 described above.

As illustrated in FIG. 4, element regions Sa of second layer L2 are formed above interlayer insulating film 9. Element regions Sa are formed of silicon films 10 being formed of a polysilicon doped with impurities such as a P type boron (B). As illustrated in FIGS. 3 and 4, element regions Sa extend in the Y direction and are spaced from one another in the X direction by a predetermined distance.

Tunnel insulating films 11 and charge storing layers FG are formed above element regions Sa of second layer L2. Element isolation regions Sb are formed between element regions Sa, between tunnel insulating films 11, and between charge storing layers FG. Element isolation regions Sb of second layer L2 are formed for example by being filled with silicon oxide films serving as element isolation films 12.

IPD films 13 are formed above charge storing layers FG and control electrodes CG are further formed above IPD films 13. Control electrodes CG serve as word lines WL and are formed of conductive layers 14. Conductive layers 14 are made of the same materials as conductive layers 8. Interlayer insulating film 15 made of for example a silicon oxide film is formed above conductive layers 14.

As illustrated in FIG. 3, gate electrode MG and select gate electrodes SGD and SGS are formed in both first layer L1 and second layer L2 of memory-cell region M. The first embodiment is described through an example in which cell units UC are formed in a double layer of first layer L1 and second layer L2. Cell units UC may be formed in a stack of 3 or more layers in which case the structures of cell units UC will be similar to the structures described above.

As illustrated in FIG. 3, bit line contact CB is formed adjacent in the Y direction to select gate electrode SGD disposed in first layer L1 and second layer L2. Source line contact CS is formed adjacent in the Y direction to select gate electrode SGS disposed in first layer L1 and second layer L2.

These bit-line contacts CB and source-line contacts CS penetrate both interlayer insulating film 15 in second layer L2 and interlayer insulating film 9 in first layer L1 so as to extend downward from the upward direction of cell units UC in second layer L2 and contact the upper surface of semiconductor substrate 1. Source lines SL contact the upper surfaces of source-line contacts CS and bit lines BL contact the upper surfaces of bit-line contacts CB.

As illustrated in FIGS. 3 and 4, a layer (third layer L3) for forming source lines SL or the like is formed above interlayer insulating film 15, and above this layer, a layer (fourth layer L4) for forming bit lines BL or the like are formed via interlayer insulating film 16. Interlayer insulating film 16 is formed for example by a silicon oxide film or the like. Upper layer wirings (not illustrated) are further formed above bit line BL via interlayer insulating film 17.

As illustrated in FIG. 4, element isolation region Sb of dummy region DM is formed in semiconductor substrate 1 in first layer L1. The width of element isolation region Sb in dummy region DM is greater in the X direction than the widths of element isolation regions Sb in memory-cell region M. Word line WL (conductive layer 8) extending from memory-cell region M terminates above element isolation region Sb of dummy region DM.

As illustrated in FIG. 2B described earlier, peripheral-circuit transistors Trp or the like are formed in first layer L1 of peripheral circuit region P. As illustrated in the right side portion of FIG. 4, gate insulating films 21 are formed in element regions 51 of semiconductor substrate 1 of peripheral-circuit region P. Conductive layer 22 is formed above gate insulating film 21 in each element region 51. Conductive layer 22 may include the same material as charge-storing layer FG. For example, conductive layer 22 may be made of polysilicon. Conductive layers 8 are further formed above conductive layers 22. Conductive layers 22 and conductive layers 8 are electrically connected by direct contact.

Contact CP1 is provided above conductive layer 8 which is provided in each element region 51. Upper layer wirings 23 are provided in third layer L3 of peripheral-circuit region P and upper layer wirings 24 are provided in fourth layer L4 of peripheral-circuit region P. Upper layer wirings 23 and upper layer wirings 24 are electrically connected to various types of components of peripheral circuit PC in peripheral-circuit region P in order to provide predetermined signals to conductive layers 8 from the components of peripheral-circuit PC.

Contacts CP1, formed above conductive layers 8, electrically connect upper layer wirings 23 in third layer L3 with conductive layer 8 in first layer L1. Contacts CP1 extend from third layer L3 to first layer L1 and thus, penetrate vertically through second layer L2. Further, contacts CP3 penetrate through interlayer insulating film 16 between upper layer wirings 23 and upper layer wirings 24.

As described earlier, element regions Sa made of polysilicon film 10, tunnel insulating films 11, charge storing layers FG, IPD films 13, and conductive layers 14 are stacked one above the other in second layer L2 of memory-cell region M. Likewise, element regions Sa, tunnel insulating films 11, and charge storing layers FG are stacked above interlayer insulating film 9.

Next, the stacks of element regions Sa, tunnel insulating films 11, and charge storing layers FG will be described as stacked structures G. Element regions Sa in second layer L2 of dummy region DM and peripheral-circuit region P serve as dummy element regions (See FIG. 4). Further, tunnel insulating films 11 and charge storing layers FG in second layer L2 of dummy region DM and peripheral-circuit region P also serve as dummy tunnel insulating films and dummy charge storing layers, respectively.

Peripheral-circuit region P is located in the periphery of memory-cell region M. Peripheral-circuit region P and memory-cell region M are formed in the order of first layer L1, second layer L2, third layer L3, and so on. Elements disposed in the same layer are formed simultaneously in memory-cell region M and peripheral-circuit region P. For example, it is supposed that stacked structures G are formed only in memory-cell region M of second layer L2 and nothing is formed in peripheral-circuit region P of second layer L2 at this phase of manufacturing process flow. In such case, the so-called dishing may occur when CMP for example is used for planarization using charge storing layers FG in memory-cell region M as a stopper (cap films or mask pattern MK (later described) disposed above charge storing layers FG may be used as a stopper). As a result, only peripheral-circuit region P may become significantly depressed.

Thus, in the first embodiment, stacked structures G are disposed in dummy region DM and in peripheral-circuit region P of second layer L2 as was the case in memory-cell region M. In the first embodiment, the X-direction widths of stacked structures G are substantially equal between regions P, M, and DM. The X-direction spacing between stacked structures G are also substantially equal between regions P, M, and DM.

In the first embodiment, stacked structures G serve as dummy stacked structures in peripheral-circuit region P and dummy region DM. Thus, contacts CP1 or the like may contact some of stacked structures G in peripheral-circuit region P and dummy region DM. However, such stacked structures G are electrically insulated from other stacked structures G.

Thus, contacts CP1 for example connect electrically to conductive layers 8 without short circuiting with other contacts CP.

In the first embodiment, stacked structures G in second layer L2 are formed substantially uniform throughout memory-cell region M, peripheral-circuit region P, and dummy region DM. Thus, it is possible to form structures without dishing even when planarization by CMP is required. Further, it is possible to reduce the stress originating from differences in the structures of each region and prevent collapse of stacked structures of second layer L2 since the stacked structures are substantially uniform throughout the memory-cell region M, peripheral-circuit region P, and dummy region DM.

Next, a description will be given on one example of a manufacturing process flow of the semiconductor device of the first embodiment. The following descriptions will focus on the features of the first embodiment. Further required steps or known steps may be added to the process flow. The sequence of the process steps may be rearranged if practicable.

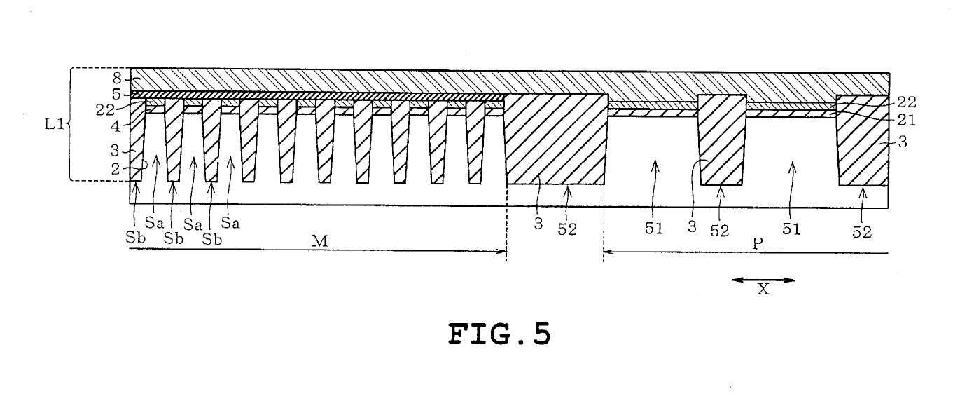

A brief description will be given on the manufacturing process flow up to the cross-sectional structure illustrated in FIG. 5. First, semiconductor substrate 1 is prepared. One example of semiconductor substrate 1 may be a P type single crystal silicon substrate. Then, tunnel insulating film 4 is formed above the surface of semiconductor substrate 1. Tunnel insulating film 4 may be formed of for example a silicon oxide film by thermal oxidation.

Tunnel insulating film 4 serves as a gate insulating film of memory-cell transistor Trm. A silicon film, ultimately serving as charge storing layer FG, is formed above tunnel insulating film 4 by CVD for example. At the same time, conductive layer 22 is formed in peripheral circuit region P. Reference symbol 22 will be appended to the silicon film hereinafter for ease of explanation. Silicon film 22 is amorphous when formed but is later transformed into polysilicon by thermal treatment.

A mask pattern is formed above silicon film 22. Using the mask pattern as a mask, element isolation trenches 2 are formed along the Y direction to obtain a line-and-space pattern. Element isolation trenches 2 in dummy region DM and peripheral-circuit region P are formed so that their widths are wider in the X direction than the widths of element isolation trenches 2 in memory-cell region M. Element isolation trenches 2, isolating element regions 51 in the shape of an island, are also formed so that their widths are wider in the X direction than the widths of element isolation trenches 2 in memory-cell region M.

Element isolation trenches 2 are filled with element isolation films 3 by CVD. The upper portions of element isolation films 3 are planarized or etched back to expose the upper surfaces of silicon films 22. A charge trap film may be formed as required by CVD. IPD film 5 is formed by LP-CVD or the like along the upper surface and the upper side surfaces of silicon film 22 and along the upper surface of element isolation film 3.

Trenches are formed in IPD films 5 of select gate electrodes SGD and SGS and IPD films 5 of peripheral circuit region P are removed. Then, conductive layer 8 is formed by stacking low-resistance metal layer such as tungsten above element isolation films 3, IPD film 5, and silicon films 22. The structure illustrated in FIG. 5 is obtained in the above described manner.

Then, conductive layer 8 disposed above element isolation film 3 located between memory-cell region M and peripheral-circuit region P and conductive layer 8 disposed above conductive layer 22 located in peripheral circuit region P are divided by anisotropic etching. Interlayer insulating film 9 is deposited by CVD so as to fill the gaps between the divided conductive layers 8.

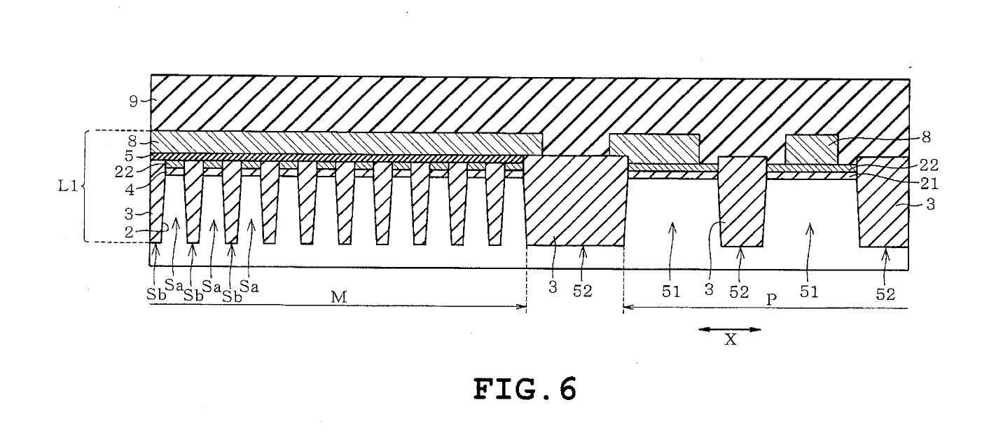

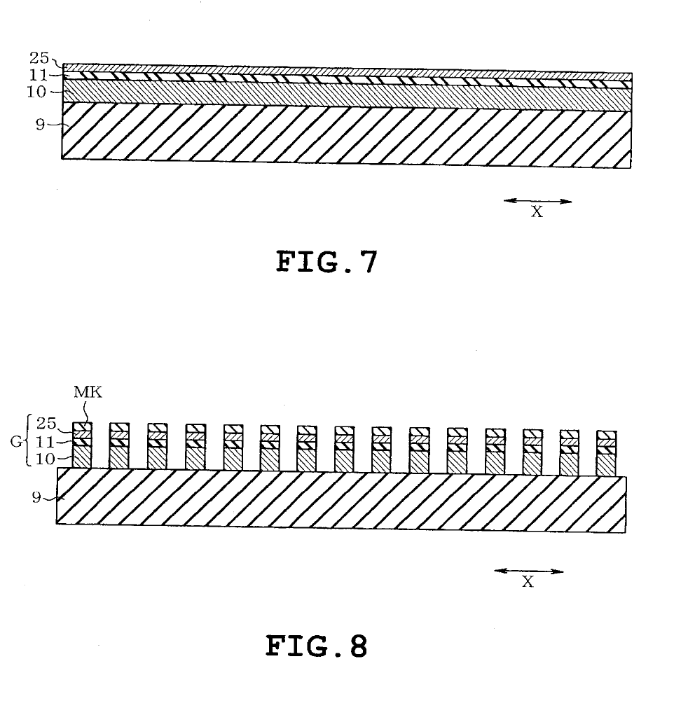

FIGS. 7 to 10 schematically illustrate the manufacturing process flow of second layer L2 following the manufacturing process illustrated in FIG. 6. FIGS. 7 to 10 schematically illustrate only interlayer insulating film 9 and the structures above interlayer insulating film 9 and the structures of first layer L1 are not illustrated.

Referring to FIG. 7, amorphous silicon film 10 is formed above interlayer insulating film 9 and silicon film 10 is doped for example with P type impurities by ion implantation. This region doped with impurities serves as element region Sa of second layer L2. Tunnel insulating film 11 is formed above silicon film 10 by for example thermal oxidation. Silicon film 25 is formed above tunnel insulating film 11 by for example CVD.

Referring to FIG. 8, mask pattern MK is formed above silicon film 25 by pattern formation methods such as a sidewall transfer technique. Mask pattern MK is a line-and-space pattern in which the ratio of the line width and the space width is approximately 1:1. Then, silicon film 25, tunnel insulating film 11, and silicon film 10 are anisotropically etched one after another. As a result, stacked structures G of second layer L2 having equal X-direction widths and X-direction spaces are formed. The X-direction widths of stacked structures G may be equal to the X-direction widths of element regions Sa of first layer L1. The line-and-space pattern may be formed by an ordinary lithography process.

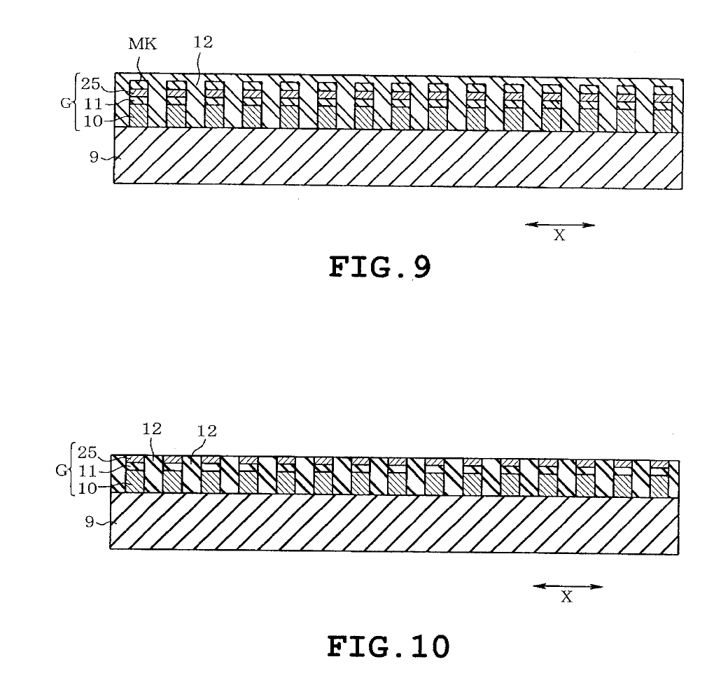

Referring to FIG. 9, stacked structures G of second layer L2 are covered by depositing for example a silicon oxide film by CVD. The silicon oxide film serves as element isolation film which constitutes element isolation region Sb. Stacked structures G are formed at substantially identical pitches (spaces) in the step immediately before the formation of element isolation film 12. Thus, element isolation film 12 can be filled well between stacked structures G even if the silicon oxide film, serving as element isolation film 12, is formed by CVD. Element isolation film 12 may be formed between stacked structures G by using for example coating-type oxide fill materials.

Referring to FIG. 10, the upper surface of the silicon oxide film serving as element isolation film 12 is planarized by CMP using the upper surface of mask pattern MK as a stopper. As a result, the height of the upper surfaces of element isolation films 12 become equal to the height of the upper surfaces of charge storing layers FG. Then, the entire surface is etched back so that the upper surfaces of charge storing layers FG and silicon oxide films are substantially coplanar. Thereafter, mask pattern MK is removed. As a result, it is possible to prevent dishing of dummy region DM and peripheral-circuit region P.

Referring to FIG. 4, IPD film 13 and conductive layer 14 are formed in memory-cell region M by for example LP-CVD. Thereafter, interlayer insulating film 15 is further deposited. IPD film 13 and conductive layer 14 are not formed in peripheral-circuit region P.

Referring to FIGS. 3 and 4, via holes are formed through interlayer insulating film 15 in peripheral-circuit region P so as to reach the upper surface of conductive layer 8 of first layer L1. Via holes are formed through interlayer insulating film 15 in memory-cell region M for forming source-line contacts CS.

Referring to FIGS. 3 and 4, contacts CP1 and CS are formed in the via holes. In peripheral-circuit region P, upper-layer wirings 23 for applying voltage to peripheral transistors Trp are formed above contacts CP1. In memory-cell region M, source line SL is formed above source-line contacts CS.

Contact CP1 in peripheral-circuit region P contacts some of stacked structures G in second layer L2. However, because stacked structures G of peripheral-circuit region P are dummy structures, it is possible to form contacts CP1 without short circuiting other contacts, or the like. Then, interlayer insulating film 16 is formed and contacts CP3, the structures of fourth layer L4 such as bit lines BL and upper-layer wirings 24 are formed.

In the first embodiment, dummy stacked structures G (dummy element regions Sa) are formed in peripheral-circuit region P. Thus, it is possible to prevent dishing caused by CMP and thereby inhibit formation of global steps. As a result, it is possible to secure planarity of the entire chip after the formation of second layer L2. Similar effects can be obtained by forming dummy stacked structures G in peripheral-circuit region P even when cell units UC are formed in third layer L3 or above.

In the first embodiment, the ratio of the line width and the space width of the line-and-space pattern in second layer L2 in peripheral-circuit region P is approximately 1:1. Thus, it is possible to equalize the widths and the spaces of the structures in second layer L2 of peripheral-circuit region P to those of stacked structures G of memory-cell region M. As a result, it is possible to prevent pattern collapse caused by the difference in the density between dense and sparse patterns.

### Second Embodiment

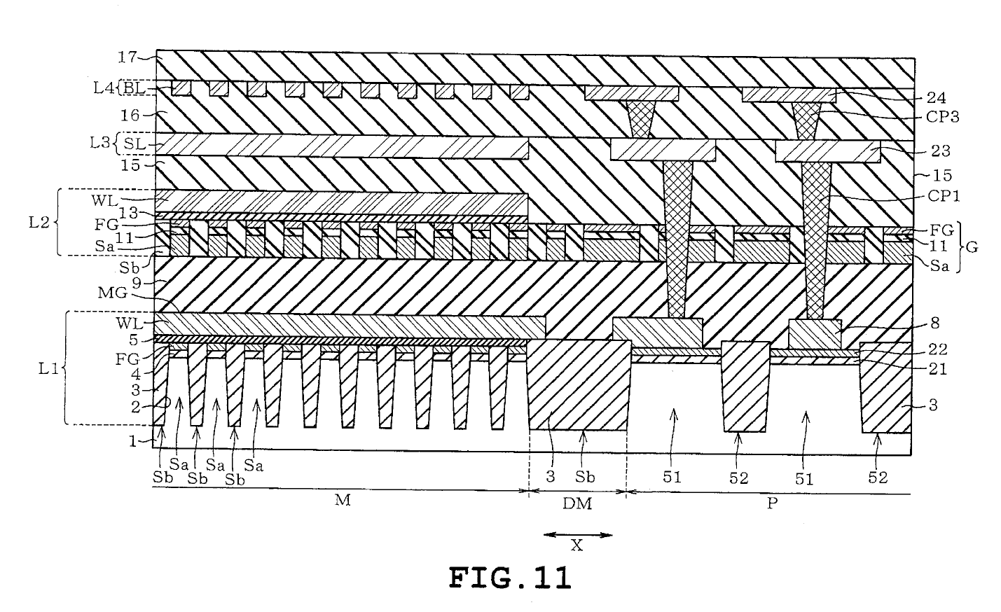

FIGS. 11 to 21 illustrate a second embodiment. The second embodiment describes an example in which the ratio (line:width) of the width of stacked structures G of second layer L2 in peripheral-circuit region P and the space between stacked gate structures G is approximately 3:1.

As illustrated in FIG. 11, the X-direction width of element regions Sa of second layer L2 in peripheral-circuit region P is approximately 3 times the X-direction width of element regions Sa of second layer L2 in memory-cell region M. Further, the spaces between element regions Sa are substantially equal in memory-cell region M and peripheral-circuit region P. Other structures are similar to those of the first embodiment and thus, will not be re-described.

A description will be given on the manufacturing process flow of the structure illustrated in FIG. 11. The manufacturing process flow of second layer L2 will be described since the structures of first layer L1, third layer L3, and fourth layer L4 are similar to those of the first embodiment.

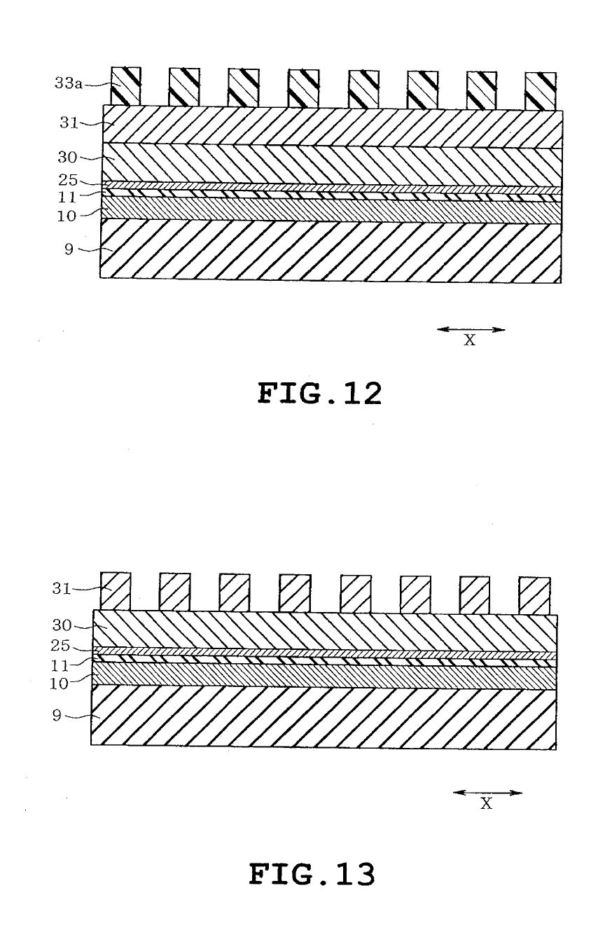

FIGS. 12 to 21 schematically illustrate the manufacturing process flow of second layer L2. Referring to FIG. 12, silicon film 10 is deposited above interlayer insulating film 9 serving as a boundary between first layer L1 and second layer L2. P type impurities are introduced into silicon film 10 by ion implantation.

Tunnel insulating film 11 is formed above silicon film 10 and polysilicon film 25, serving as charge storing layer FG, is formed above tunnel insulating film 11. Silicon nitride film 30 is formed above polysilicon film 25 by CVD for example and silicon oxide film 31 is formed above silicon nitride film 30 by CVD for example.

Resist 33a is coated above silicon oxide film 31 and resist 33a is patterned into a line-and-space a pattern in which the ratio of width of line and space is approximately 1:1. The line width and the space width of the line-and-space pattern are configured at critical dimension.

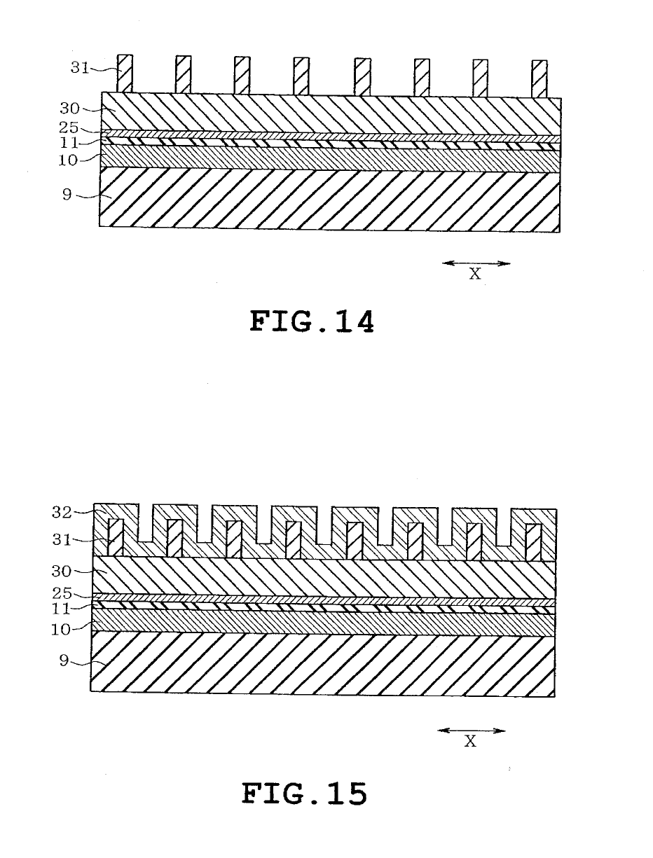

Referring to FIG. 13, using the patterned resist 33a as a mask, silicon oxide film 31 is anisotropically etched by RIE. Then, the patterned resist 33a is removed by asking or the like. Referring to FIG. 14, silicon oxide films 31 are thinned using a slimming technique. Silicon oxide films 31 are thinned so that the X-direction space width between the adjacent silicon oxide films 31 is substantially 3 times of the X-direction line width of a single line of silicon oxide film 31.

Referring to FIG. 15, using CVD, ALD, or the like, amorphous silicon film 32 is formed so as to extend along the upper surfaces and side surfaces of silicon oxide films 31 and along the exposed upper surfaces of silicon nitride film 30. Amorphous silicon film 32 is formed at a thickness substantially equal to the X-direction width of silicon oxide film 31.

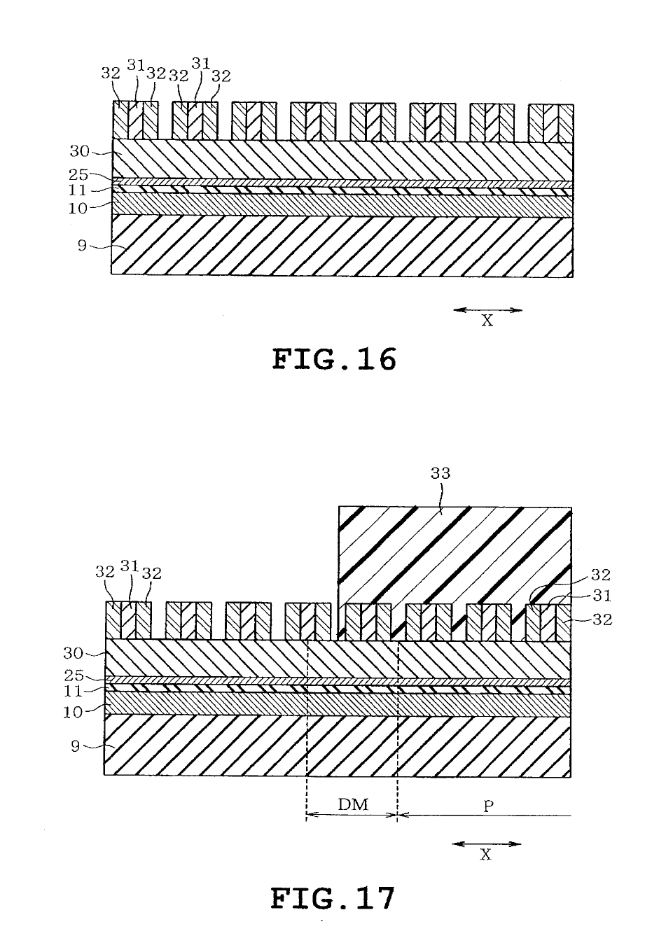

Referring to FIG. 16, amorphous silicon film 32 is selectively and anisotropically etched by RIE. As a result, amorphous silicon films 32 along the upper surfaces of silicon oxide films 31 and along the upper surface of silicon nitride film 30 are removed, while amorphous silicon films 32 along the side surfaces of silicon oxide films 31 remain unremoved. As a result, it is possible to expose the upper surfaces of silicon nitride film 30.

As illustrated in FIG. 17, resist 33 is coated and patterned so as to cover amorphous silicon films 32, silicon oxide films 31, and silicon nitride film 30 which are located in dummy region DM and peripheral-circuit region P.

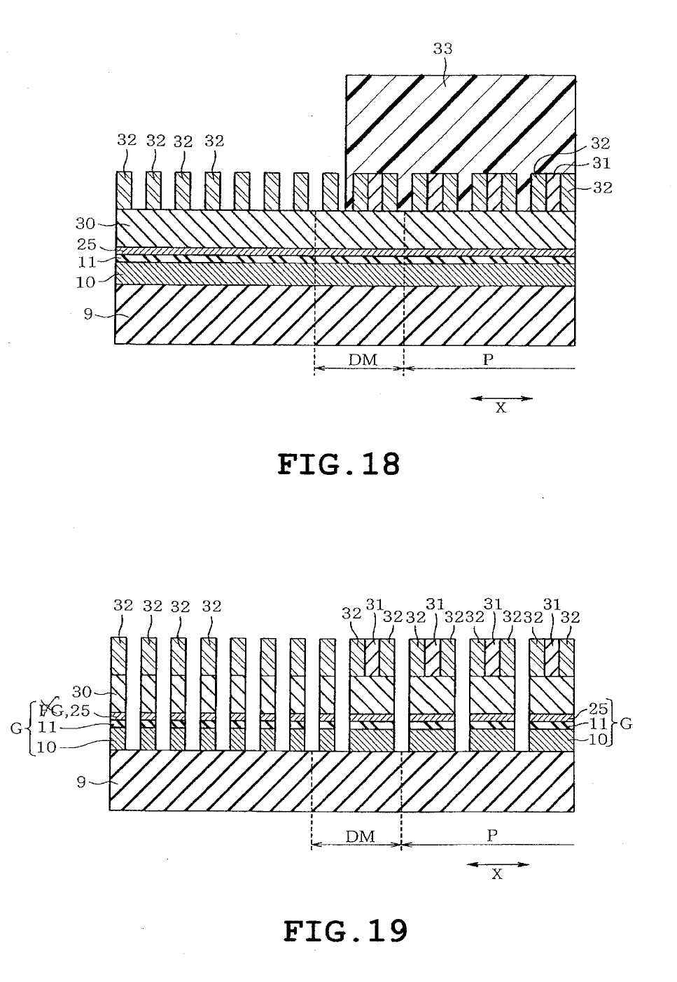

Referring to FIG. 18, in the region which is not covered by the patterned resist 33 such as memory-cell region M, silicon oxide films 31 are selectively etched to selectively remove silicon oxide films 31 located between adjacent amorphous silicon films 32.

Then, resist 33 is removed and as illustrated in FIG. 19, silicon nitride film 30 is anisotropically etched by RIE with a higher etching selectivity than silicon oxide films 31 and amorphous silicon films 32.

Thereafter, etching conditions are modified and using silicon nitride films 30 as masks, silicon film 25 serving as charge storing layer FG, tunnel insulating film 11, and silicon film 10 are anisotropically etched by RIE. Stacked structures G of second layer L2 are formed in the above described manner.

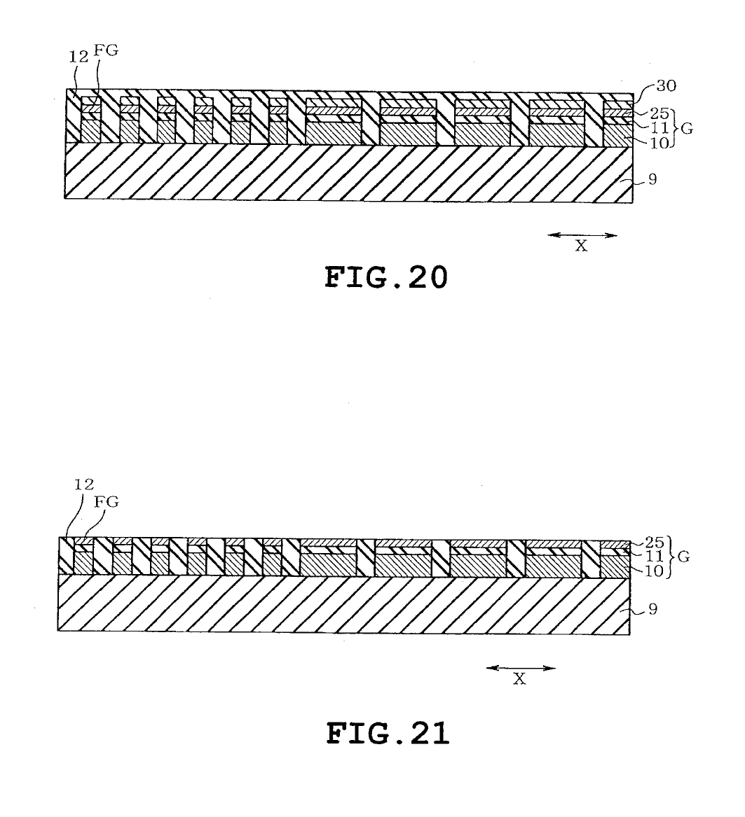

Then, as illustrated in FIG. 20, element isolation film 12 is formed between stacked gate structures G. Element isolation film 12 may be formed of for example a silicon oxide film formed by CVD. Then, planarization is carried by CMP using the mask films (silicon nitride films 30) as stoppers. Stacked structures G are formed in dummy region DM and peripheral-circuit region P in the above described manner. As a result, it is possible to prevent dishing in dummy region DM and peripheral-circuit region P. Then, as illustrated in FIG. 21, the upper portions of element isolation films 12 are etched back so as to be coplanar with the upper surfaces of charge storing layers FG and silicon nitride films 30 are removed to expose the upper surfaces of charge storing layers FG.

Element regions Sa are formed in second layer L2 of peripheral-circuit region P in the second embodiment as well and thus, it is possible to achieve planarity of the entire chip after formation of second layer L2. Further, there is no need to use coating-type silicon oxide film, serving as element isolation film 12 and the fill material for filling the gaps between element regions Sa, but instead, it is possible to use a CVD film having good coverage. Further, element regions Sa which are approximately 3 times wider than element regions Sa located in memory-cell region M are formed in dummy region DM and peripheral-circuit region P. Thus, it is possible to improve the mechanical strength of the patterns and reduce the possibilities of occurrences pattern collapse, or the like, during the manufacturing process flow.

Still further, the second embodiment was described through an example in which wide dummy stacked structures G which are approximately 3 times wider than those of memory-cell region M are provided in dummy region DM and peripheral-circuit region P. However, stacked structures having widths that are substantially the same as the stacked structures in memory-cell region M may be formed in dummy region DM. Further, wide dummy stacked structures G which are approximately 3 times wider than those of memory-cell region M may be provided in a portion of peripheral-circuit region P.

### Third Embodiment

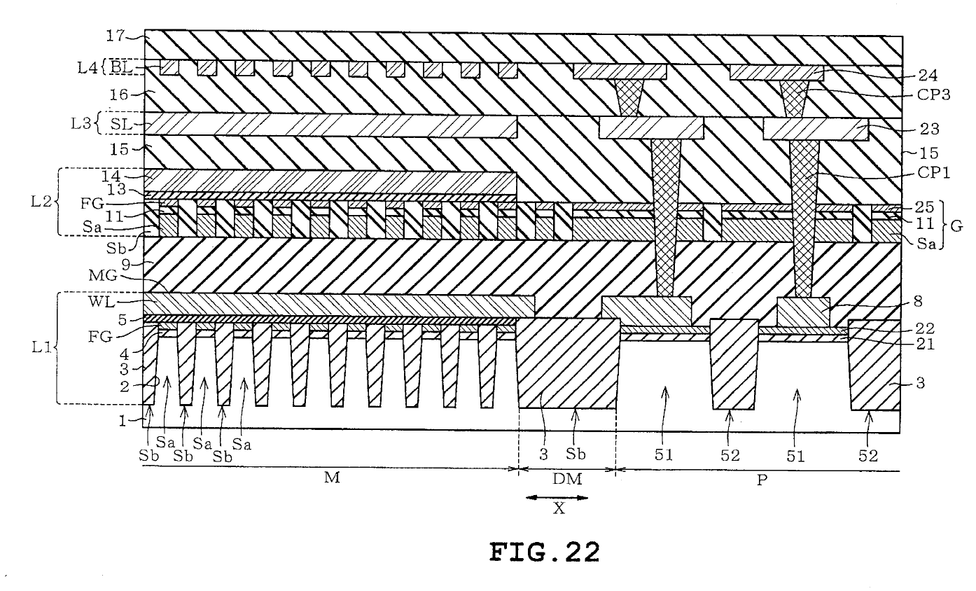

FIG. 22 to FIG. 41 illustrate a third embodiment. The third embodiment describes an example in which the ratio (line:width) of the width of stacked structures G of second layer L2 in peripheral-circuit region P and the space between stacked gate structures G is approximately 7:1.

As illustrated in FIG. 22, the X-direction width of element regions Sa of second layer L2 in peripheral-circuit region P is approximately 7 times the X-direction width of element regions Sa of second layer L2 in memory-cell region M. Further, the spaces between element regions Sa are substantially equal in memory-cell region M and peripheral-circuit region P. Other structures are similar to those of the first embodiment and thus, will not be re-described.

A description will be given on the manufacturing process flow of the structure illustrated in FIG. 22. The manufacturing process flow of second layer L2 will be described since the structures of first layer L1, third layer L3, and fourth layer L4 are similar to those of the foregoing embodiments.

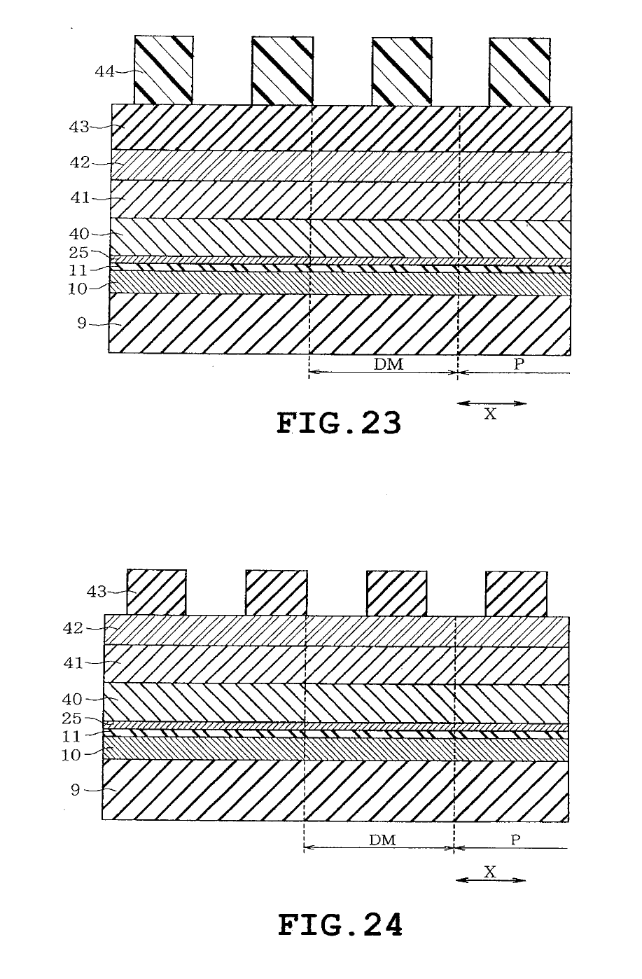

FIGS. 23 to 41 schematically illustrate the manufacturing process flow of second layer L2. Referring to FIG. 23, silicon film 10 is deposited above interlayer insulating film 9 serving as a boundary between first layer L1 and second layer L2. P type impurities are introduced into silicon film 10 by ion implantation.

Tunnel insulating film 11 is formed above silicon film 10 and silicon film 25, serving as charge storing layer FG, is formed above tunnel insulating film 11. Silicon nitride film 40, silicon oxide film 41, amorphous silicon film 42, and silicon oxide film 43 are formed one after another above silicon film 25 by CVD for example.

Resist 44 is coated above silicon oxide film 43 and resist 44 is patterned into a line-and-space a pattern in which the ratio of width of line and space is approximately 1:1. The line width and the space width of the line-and-space pattern are configured at critical dimension.

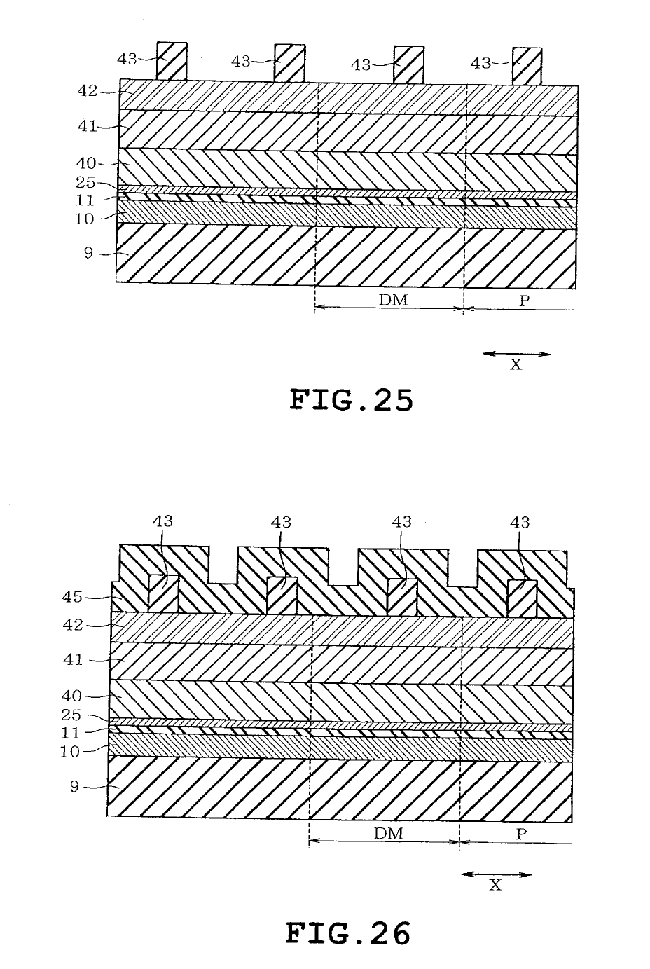

Referring to FIG. 24, using the patterned resist 44 as a mask, silicon oxide film 43 is anisotropically etched by RIE. Then, the patterned resist 44 is removed by ashing or the like. Referring to FIG. 25, silicon oxide films 43 are thinned using a slimming technique. Silicon oxide films 43 are thinned so that the X-direction space width between the adjacent silicon oxide films 43 is substantially 3 times of the X-direction line width of a single line of silicon oxide film 43 (slimming process).

Referring to FIG. 26, using CVD, ALD, or the like, silicon nitride film 45 is formed so as to extend along the upper surfaces and side surfaces of silicon oxide films 43 and along the exposed upper surfaces of amorphous silicon film 42. Silicon nitride film 45 is formed at a thickness substantially equal to the X-direction width of silicon oxide film 43.

Referring to FIG. 27, silicon nitride film 45 is selectively and anisotropically etched by RIE. As a result, silicon nitride films 45 along the upper surface of amorphous silicon film 42 and along the upper surfaces of silicon oxide films 43 are removed, while silicon nitride films 45 along the side surfaces of silicon oxide films 43 remain unremoved. As a result, it is possible to expose the upper surfaces of amorphous silicon film 42.

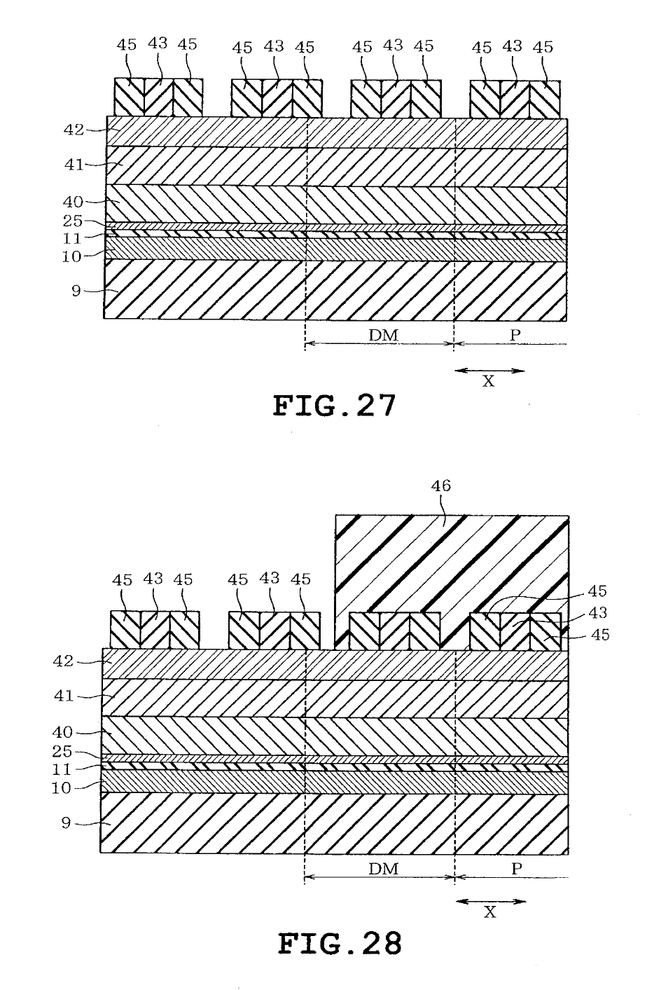

As illustrated in FIG. 28, resist 46 is coated and patterned so as to cover silicon nitride films 45, silicon oxide films 43, and amorphous silicon film 42 which are located in dummy region DM and peripheral-circuit region P.

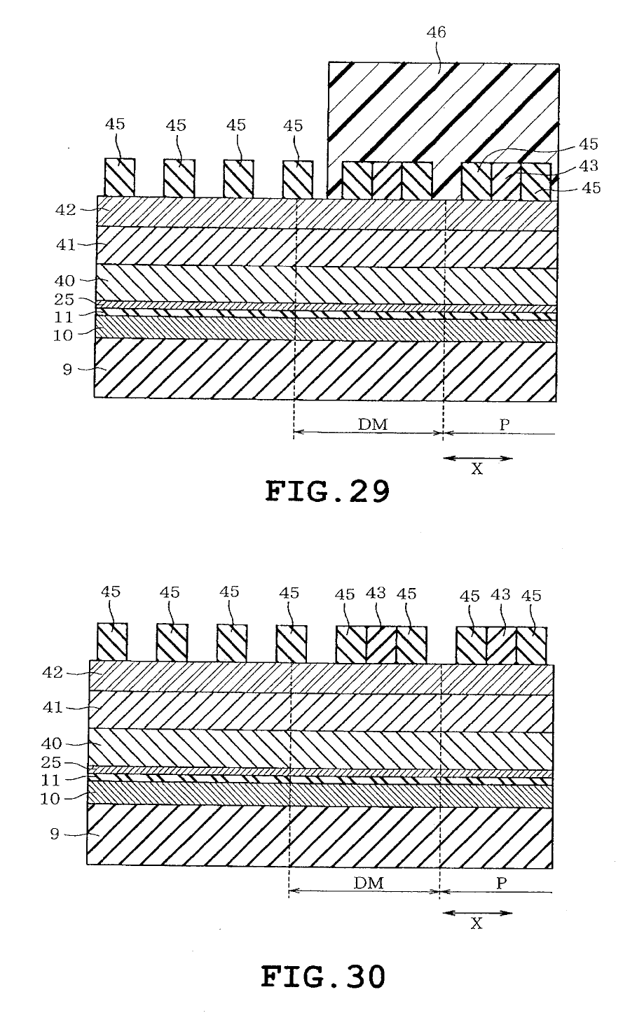

Referring to FIG. 29, in the region which is not covered by the patterned resist 46 such as memory-cell region M (and dummy region DM if required), silicon oxide films 43 are selectively etched to selectively remove silicon oxide films 43 located between adjacent silicon nitride films 45. Referring to FIG. 30, resist 46 is removed.

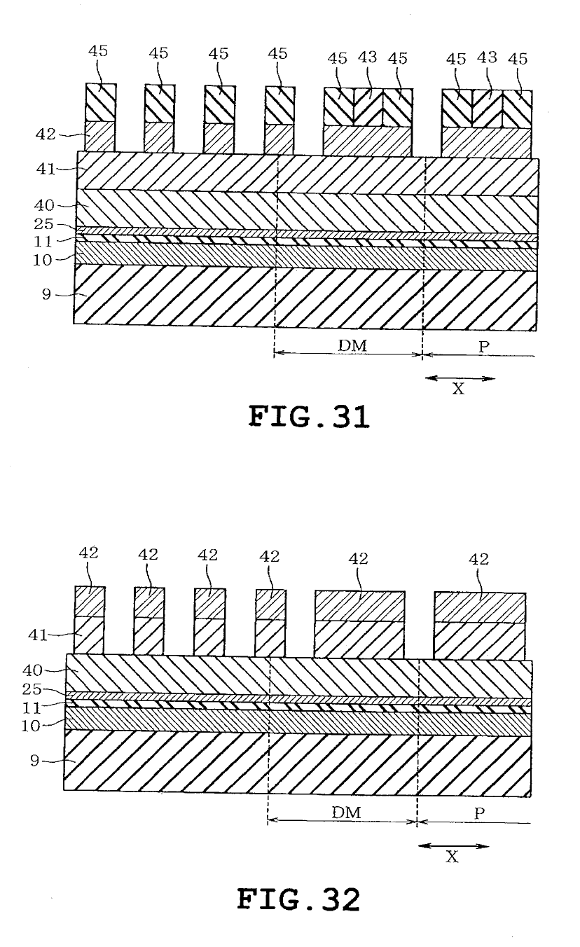

Referring now to FIG. 31, amorphous silicon films 42 are anisotropically etched by RIE with a higher etching selectivity than silicon oxide films 43 and silicon nitride films 45. Then, etching conditions are modified and silicon oxide film 41 is anisotropically etched by RIE using the remaining amorphous silicon films 42 as masks as illustrated in FIG. 32.

Thus, it is possible to configure the ratio of the line width and the space width of silicon oxide films 41 in memory-cell region M (and in dummy region DM if required) at approximately 1:1, while configuring the ratio of the line width and the space width of silicon oxide films 41 in peripheral-circuit region P at approximately 3:1.

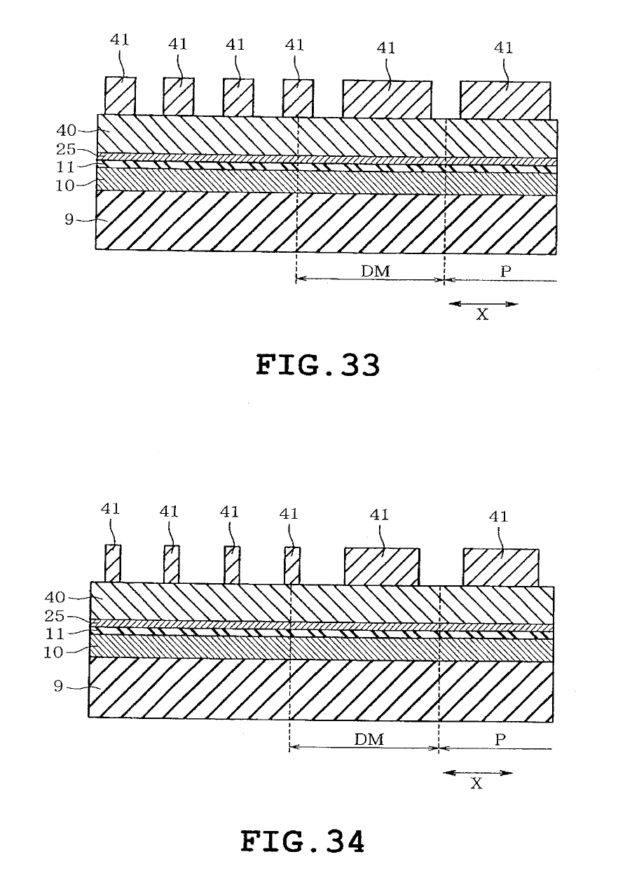

Referring to FIG. 33, amorphous silicon films 42 remaining along silicon oxide films 41 are removed. Referring to FIG. 34, silicon oxide films 41 are thinned by slimming process. The slimming process is carried out so that when the X-direction width of each of silicon oxide films 41 in memory-cell region M is identified as 1, the X-direction width of each of silicon oxide films 41 in peripheral-circuit region P is identified as approximately 5, and the space widths between silicon oxide films in memory-cell region M, dummy region DM, and peripheral-circuit region P are identified as approximately 3.

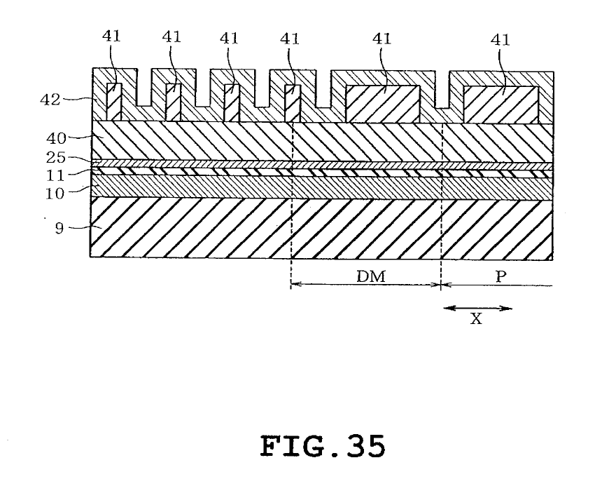

Referring to FIG. 35, using CVD, ALD, or the like, amorphous silicon film 42 is formed so as to extend along the upper surfaces and side surfaces of silicon oxide films 41 and along the exposed upper surfaces of silicon nitride film 40. Amorphous silicon film 42 is formed at a thickness substantially equal to the X-direction width of silicon oxide film 41 in memory-cell region M.

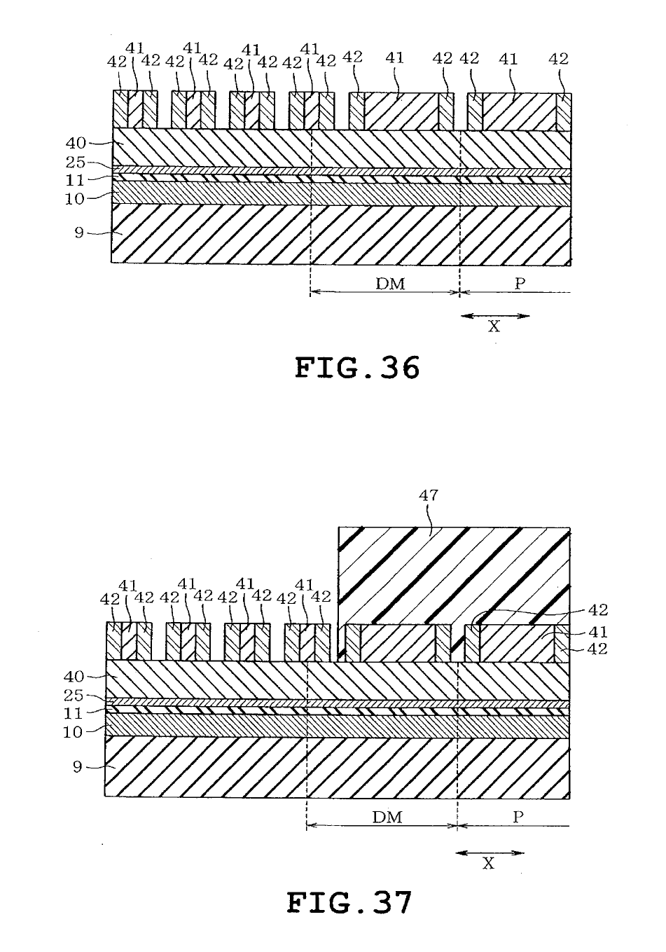

Referring to FIG. 36, amorphous silicon film 42 is selectively and anisotropically etched by RIE. As a result, amorphous silicon films 42 along the upper surfaces of silicon oxide films 41 and amorphous silicon films 42 along the upper surface of silicon nitride film 40 are removed, while amorphous silicon films 42 along the side surfaces of silicon oxide films 41 remain unremoved. As a result, it is possible to expose the upper surfaces of silicon nitride film 40.

Thus, amorphous silicon films 42 are formed along both side surfaces of silicon oxide films 41 in peripheral-circuit region P and in other regions. When the X-direction width of each of amorphous silicon films 42 is identified as 1, the X-direction width of the sum of each of silicon oxide films 41 and each of amorphous silicon films 42 in peripheral-circuit region P is identified as approximately V. In other regions (such as in memory-cell region M), the X-direction width of the sum of each of silicon oxide films 41 and each of amorphous silicon films 42 is identified as approximately 3. The space widths between these film structures are identified as 1.

As illustrated in FIG. 37, resist 47 is coated and patterned so as to cover silicon oxide films 41, amorphous silicon films 42, and silicon nitride film 40 which are located in peripheral-circuit region P.

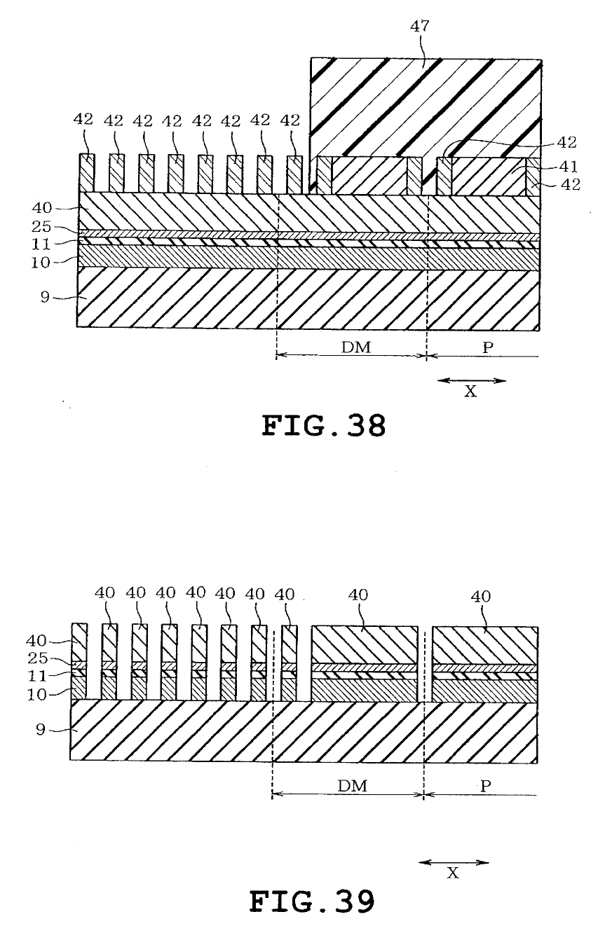

Referring to FIG. 38, in the region which is not covered by the patterned resist 47 such as memory-cell region M, silicon oxide films 41 are selectively etched to selectively remove silicon oxide films 41 located between adjacent amorphous silicon films 42.

Then, resist 47 is removed and as illustrated in FIG. 39, silicon nitride film 40 is anisotropically etched by RIE with a higher etching selectivity than silicon oxide materials and amorphous silicon films 42. Thereafter, etching conditions are modified and using silicon nitride films 40 as masks, silicon film 25 serving as charge storing layer FG, tunnel insulating film 11, and silicon film 10 are anisotropically etched by RIE as illustrated in FIG. 39.

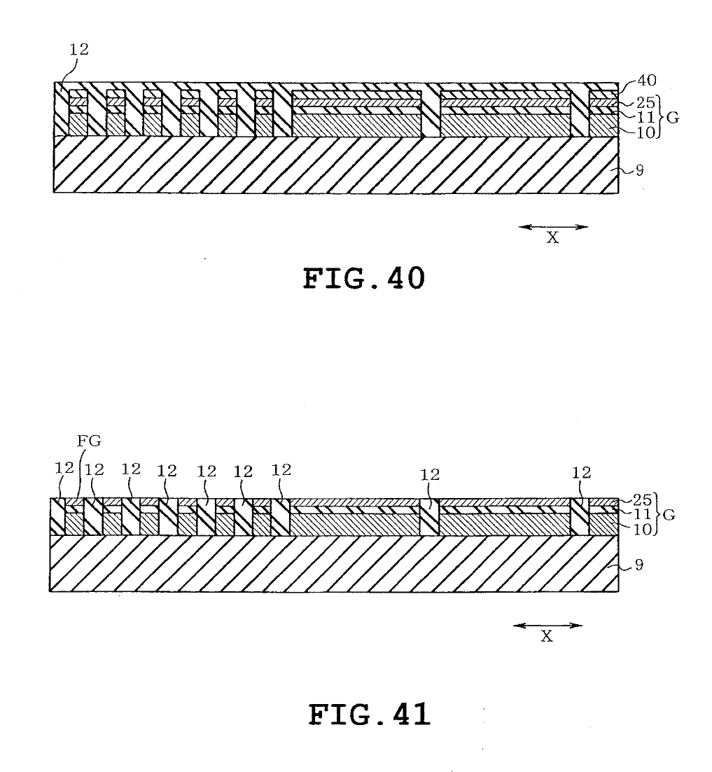

Referring to FIG. 40, element isolation film 12 is formed between stacked gate structures G. Element isolation film 12 may be formed of for example a silicon oxide film formed by CVD. Then, planarization is carried by CMP using the mask films (silicon nitride films 40) as stoppers. Stacked structures G are formed in dummy region DM and peripheral-circuit region P in the above described manner. As a result, it is possible to prevent dishing in dummy region DM and peripheral-circuit region P.

Then, as illustrated in FIG. 41, the upper portions of element isolation films 12 are etched back so as to be coplanar with the upper surfaces of charge storing layers FG and silicon nitride films 40 are removed to expose the upper surfaces of silicon films 25 (charge storing layers FG). It is possible to form stacked structures G in second layer L2 in the above described manner. As a result, when the X-direction width of each of element regions in memory-cell region M in second layer L2 is identified as 1, the X-direction width of each of element regions in peripheral-circuit region P can be identified as 7 (approximately 7 times as wide). Thus, it is possible to form increasingly wider element regions Sa in peripheral-circuit region P.

In the third embodiment, the sidewall transfer technique is repeated twice in peripheral-circuit region P to form element regions Sa each having a width which is approximately 7 times the width of each of element regions Sa in memory-cell region M. Thus, it is possible to achieve planarity of the entire chip after formation of second layer L2. Further, there is no need to use coating-type oxide film as the fill material for filling the gaps between element regions Sa, but instead, it is possible to use a CVD film having good coverage. Further, element regions Sa which are approximately 7 times wider than element regions Sa located in memory-cell region M are formed in peripheral-circuit region P. Thus, it is possible to improve the mechanical strength of the patterns and reduce the possibilities of occurrences pattern collapse, or the like, during the manufacturing process flow.

Further, it is possible to form element regions Sa (stacked structures G) each having a width approximately 5 times the width of each of element regions Sa in memory-cell region M by using a triple patterning technique in which 3 lines are split in 1 exposure. Thus, it is possible to form element regions Sa in peripheral-circuit region P each having a width which is 2n+1 (n≧0, n is an integer) times the width of each of element regions Sa in memory-cell region M.

The third embodiment was described through an example in which wide dummy stacked structures G which are approximately 2n+1 times wider than those of memory-cell region M are provided in dummy region DM and peripheral-circuit region P. However, stacked structures having widths that are substantially the same as the stacked structures in memory-cell region M may be formed in dummy region DM. Further, wide dummy stacked structures G which are approximately 2n+1 times wider than those of memory-cell region M may be provided in a portion of peripheral-circuit region P.

### Fourth Embodiment

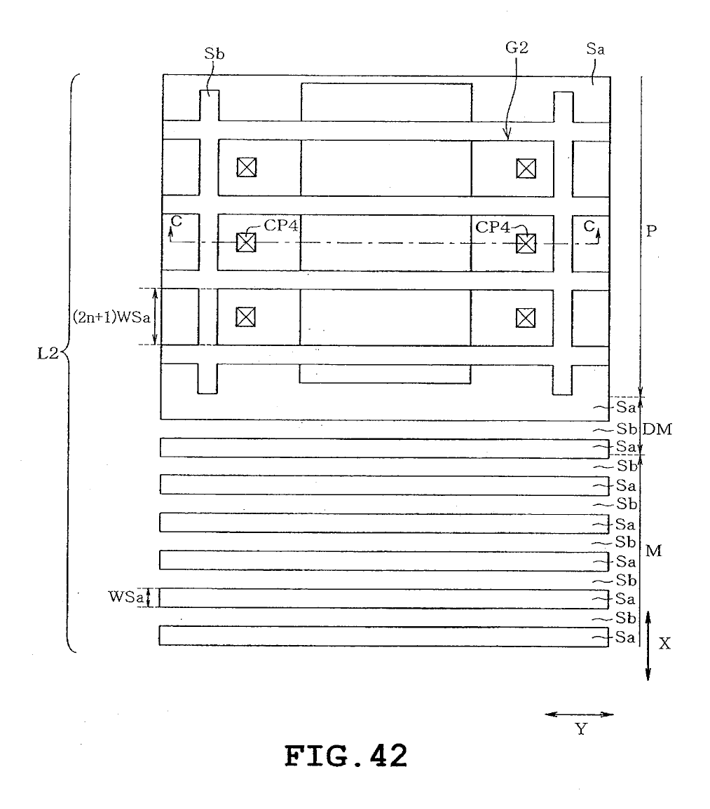

FIGS. 42 to 50 illustrate a fourth embodiment. The fourth embodiment is described through an example in which resistive element Ra and/or capacitive element Ca are provided by utilizing dummy element regions located in peripheral-circuit region P of second layer L2 or above.

For example, as described in the second or the third embodiment, it is possible to form stacked structures G in second layer L2 of peripheral-circuit region P each having an X-direction width which is 2n+1 (n≧1) times the X-direction width of each of element regions Sa of memory-cell region M.

In the fourth embodiment, a description is given with an assumption that each of stacked gate structures G2 of second layer L2 are formed of a stack of silicon film 10, tunnel insulating film 11, silicon film 25, IPD film 13, and conductive layer 14. FIG. 42 provides a plan view of stacked structure G2 of second layer L2.

As illustrated in FIG. 42, element regions Sa of memory-cell region M extend in the Y direction. Each of element regions Sa has an X-direction width WSa. In peripheral-circuit region P, stacked structures G2 of second layer L2 extend in the Y direction. Each of stacked structures G2 has width (2n+1) WSa as compared to the width WSa of each of element regions Sa of memory-cell region M. Stacked structures G2 are spaced from one another by a predetermined space in the X direction.

FIG. 42 will be described through an example in which n=1. In forming stacked structures G2, silicon film 10, tunnel insulating film 11, silicon film 25, IPD film 13, and conductive layer 14 are stacked one above the other. Then, element isolation regions Sb extending in the X direction are formed to isolate the stacked films 10, 11, 25, 13, and 14 into shapes like islands. Contacts CP4 are formed above a portion (silicon film 10) of stacked gate structures G2 so as to be spaced in the Y direction.

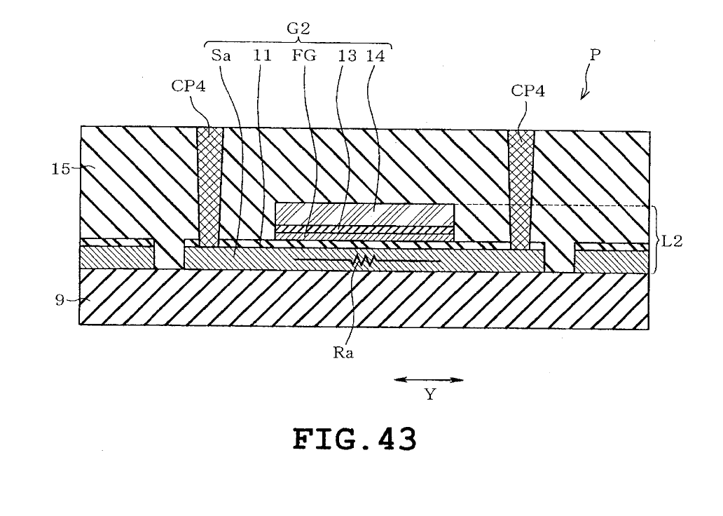

FIG. 43 illustrates one schematic example of a cross-sectional structure taken along line C-C of FIG. 42. As illustrated in FIG. 43, each of stacked structures G2 is formed of silicon film 10 serving as element region Sa, tunnel insulating film 11, silicon film 25 serving as charge storing layer FG, IPD film 13, and conductive layer 14 stacked one above the other above interlayer insulating film 9.

In each of the divided stacked structures G2, silicon film 10 and tunnel insulating film 11 are formed so as to extend in the Y direction. Charge storing layer FG, IPD film 13, and conductive layer 14 are stacked above a portion of the Y-direction center of silicon film 10 and tunnel insulating film 11.

Thus, tunnel insulating film 11 is exposed at Y direction ends of each stacked gate structure G2. Interlayer insulating film 15 is formed so as to cover stacked gate structures G2. Contacts CP4 are formed so as to extend through interlayer insulating film 15 and tunnel insulating film 11 and contact the upper surface of silicon film 10. Silicon film 10 of second layer L2 is disposed between the adjacent contacts CP4 spaced in the Y direction. Silicon film 10 serves as resistive element Ra.

A brief description is given on the manufacturing process flow of the structure illustrated in FIG. 43. The manufacturing process flow will be described based on the example of the second embodiment in which the X-direction widths of the stacked structures of second layer L2 in peripheral-circuit region P are 3 times the X-direction widths of the stacked structures of second layer L2 in memory-cell region M.

As illustrated in FIG. 21 of the second embodiment, element isolation films 12 are filled between silicon films 10, tunnel insulating films 11, and silicon films 25 and the upper surfaces of element isolation films 12 are slightly etched back. Then, IPD film 13 and conductive layer 14 are formed one above the other.

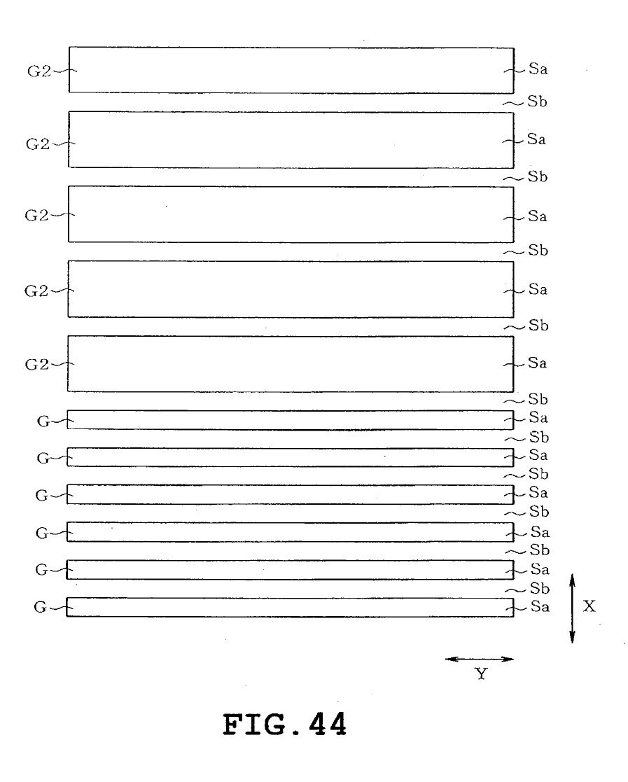

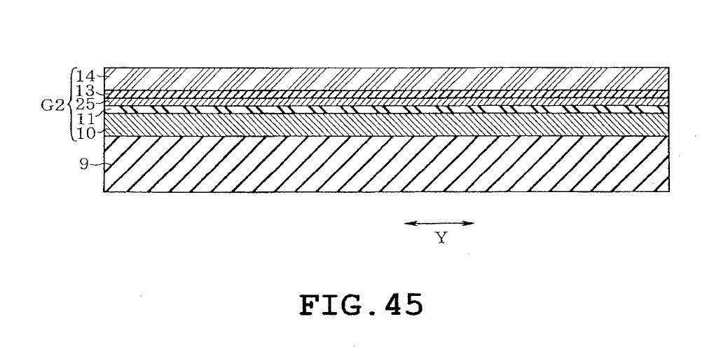

FIG. 44 illustrates the plan view of stacked structures G and G2 of second layer L2 at this phase of the manufacturing process flow. FIG. 45 illustrates the cross-sectional structure of second layer L2 taken along line C-C of FIG. 42.

As illustrated in FIG. 44, stacked structures G having X-direction widths WSa extend in the Y direction in memory-cell region M. In peripheral-circuit region P on the other hand, stacked structures G2 having X-direction widths (2n+1) WSa extend in the Y direction.

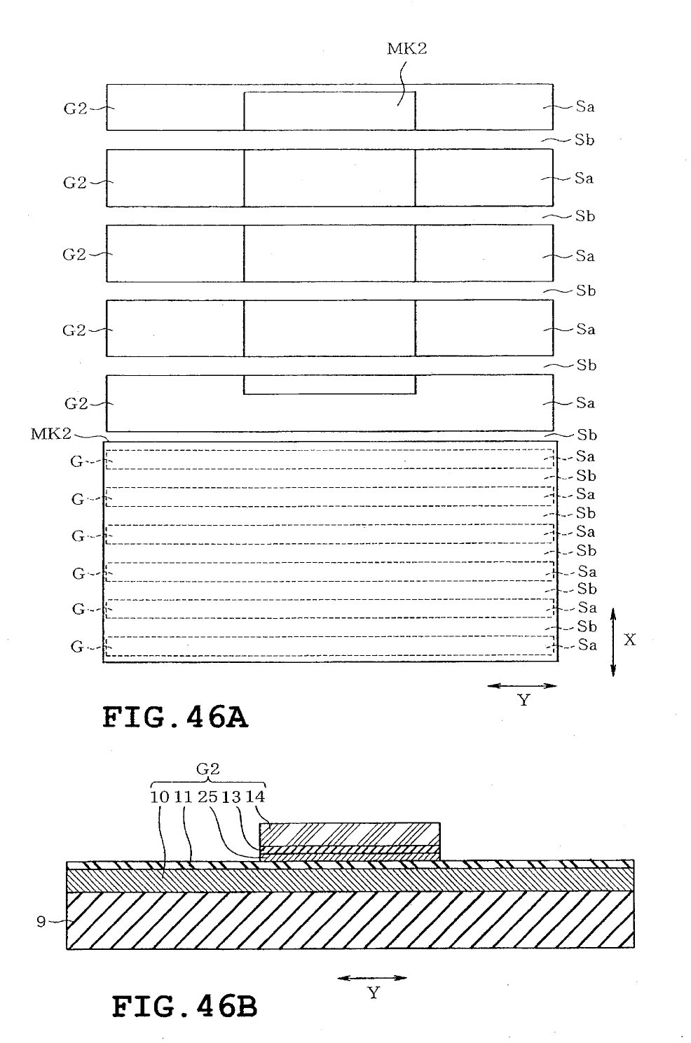

As illustrated in FIG. 46A, mask pattern MK2 is formed above stacked structures G2 disposed in the X direction. In plan view, mask pattern MK2 is formed in a central portion in the Y direction of each of tunnel insulating films 11 in which charge storing layer FG, IPD film 13, and conductive layer 14 are to be formed. Then, as illustrated in FIG. 46B, the upper layer portion (conductive layer 14, IPD film 13, silicon film 25 serving as charge storing layer FG) of each of stacked structures G2 of second layer L2 are anisotropically etched by RIE using tunnel insulating film 11 as a stopper and mask pattern MK2 as a mask. Mask pattern MK2 is thereafter removed.

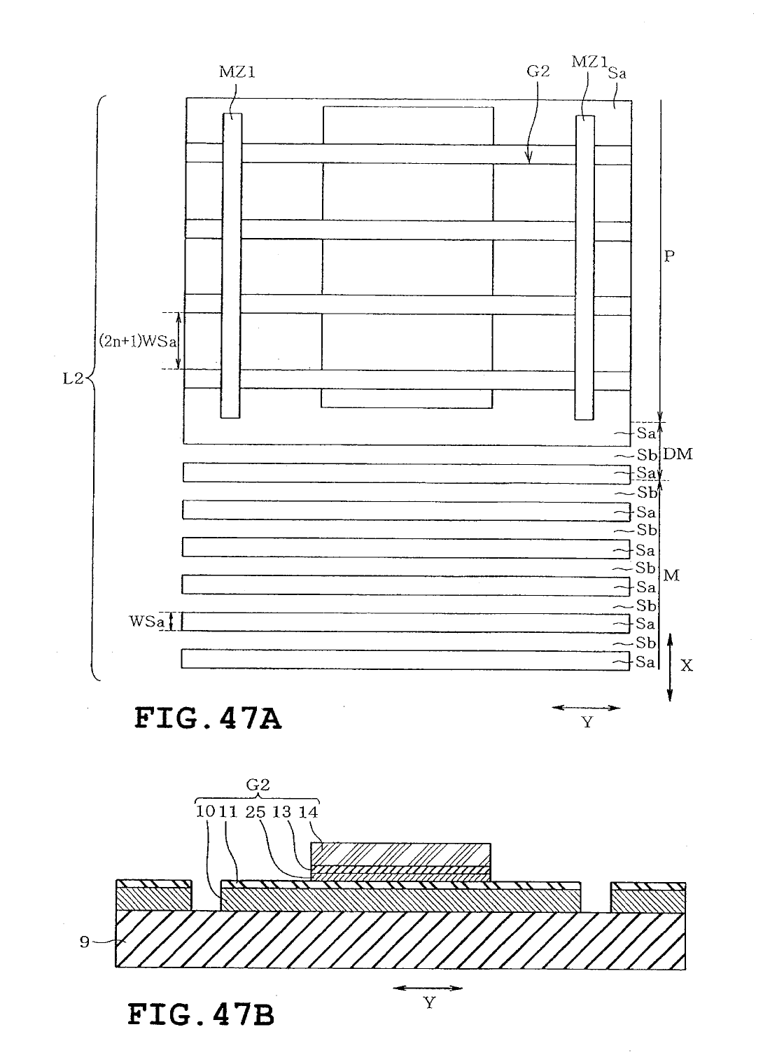

Referring to FIG. 47A, trenches MZ1 extending in the X direction are formed so as to extend across stacked structures G2 disposed in the X direction. Two trenches MZ1 are formed so as to be spaced from one another in the Y direction. Stacked structures G2 shaped like islands are formed in the portions disposed between trenches MZ1. Referring to FIG. 47B, trenches MZ1 are formed by etching tunnel insulating films 11 and silicon films 10 by RIE until the upper surfaces of interlayer insulating film 9 are exposed. The anisotropic etching is carried out in the regions corresponding to element isolation regions Sb extending along the X direction in FIG. 42 and element regions Sa shaped like islands are formed at the same time.

Referring to FIG. 43, interlayer insulating film 15 is deposited by CVD above stacked structures G and G2. Holes are formed through interlayer insulating film 15 and tunnel insulating film 11 until the upper surfaces of silicon film 10 are reached. The holes are filled with contact CP4. As a result, it is possible to form resistive element Ra between two contacts CP4.

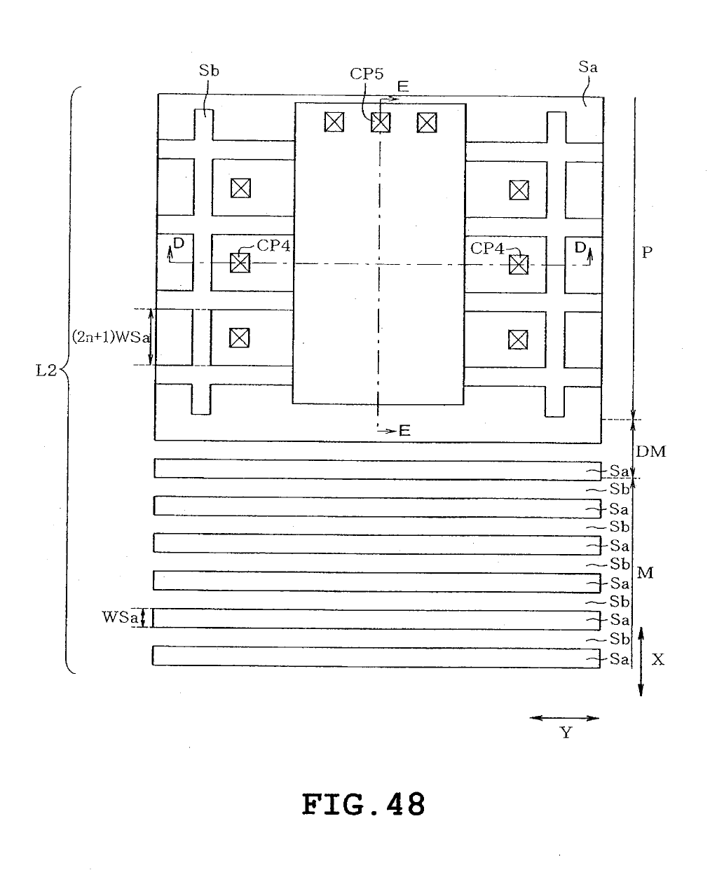

FIGS. 48 to 50B schematically illustrate the structures of capacitive elements Ca formed in second layer L2 or above. As illustrated in FIGS. 48 to 50B, capacitive elements Ca are formed using the dummy structures formed in second layer L2 of peripheral-circuit region P.

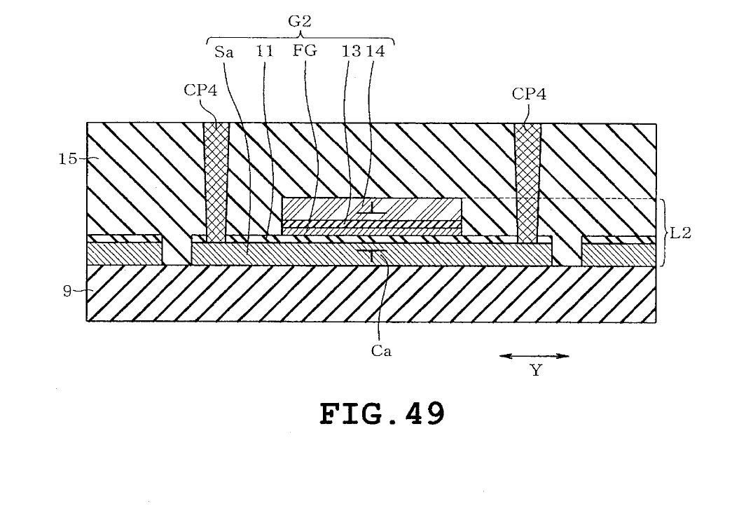

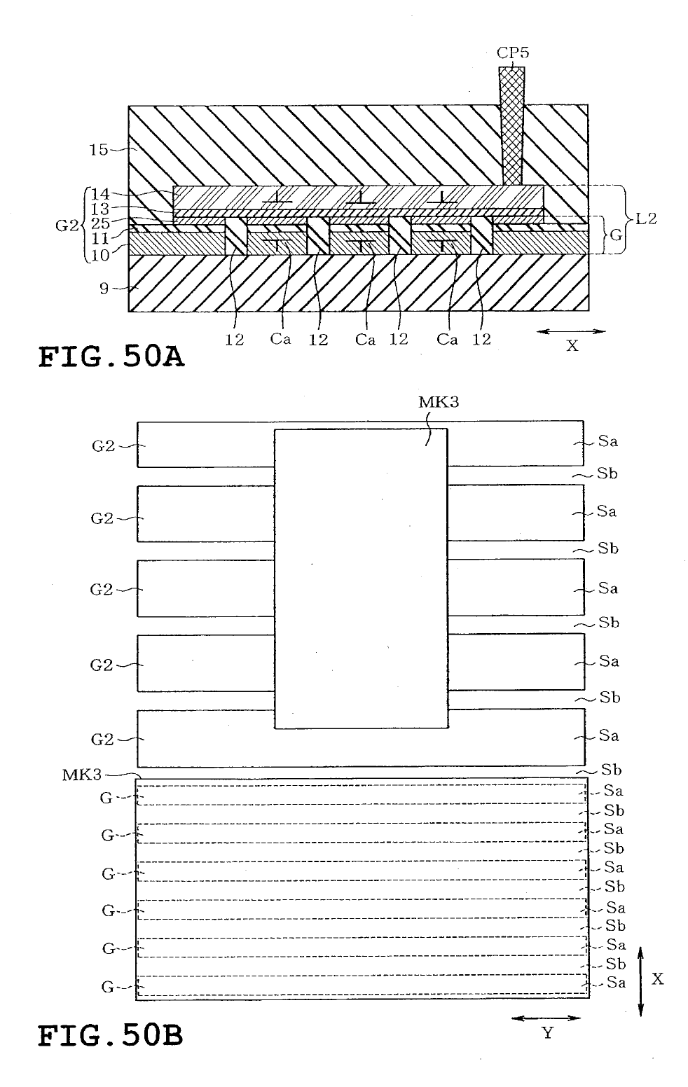

FIG. 49 schematically illustrates one example of a cross-sectional structure taken along line D-D of FIG. 48. FIG. 50A schematically illustrates one example of a cross-sectional structure taken along line E-E of FIG. 48. As illustrated in FIG. 49, the Y-direction cross-sectional structure of stacked structures G2 is substantially the same as the Y-direction cross-sectional structure of stacked structure G2 of resistive element Ra and thus, will not be described.

As illustrated in FIG. 50B, element regions Sa of memory-cell region M extend in the Y direction. Each of element regions Sa has an X-direction width WSa. In peripheral-circuit region P, stacked structures G2 of second layer L2 extend in the Y direction. Each of stacked structures G2 has width (2n+1) WSa as compared to the width WSa of each of element regions Sa of memory-cell region M. Stacked structures G2 are spaced from one another by a predetermined distance in the X direction.

FIGS. 49 to 50B will be described through an example in which n=1. In forming stacked structures G2, silicon film 10, tunnel insulating film 11, silicon film 25, IPD film 13, and conductive layer 14 are stacked one above the other. Then, element isolation regions Sb extending in the X direction are formed to isolate the stacked films 10, 11, 25, 13, and 14 into shapes like islands. As illustrated in FIG. 49, contacts CP4 are formed above a portion (silicon film 10) of stacked gate structures G2 so as to be spaced in the Y direction.

As viewed in FIG. 49, IPD films 13 are formed above stacked structures G2 so as to be located near the Y-direction central portion of each stacked structure G2. As viewed in FIG. 50A, IPD films 13 are formed continuously above stacked structures G2 disposed in the X direction so as to cover the upper surfaces of silicon films 25 and element isolation films 12. Conductive layers 14 are formed above IPD films 13. Via contacts CP5 are formed to extend through interlayer insulating film 15 so as to be located above the X-direction end of conductive layer 14.

Stated differently, IPD films 13 and conductive layers 14 are formed so as to extend above stacked structures G and element isolation films 12 in the X direction as illustrated in FIG. 50A. Further, IPD films 13 and conductive layers 14 project outward in the X direction from portions (stacked structures G) serving as elements of capacitive elements Ca. Via contact plugs CP5 are disposed above stacked structures G located below the projecting portions. Stated yet differently, capacitive elements Ca are formed so as to be disposed toward the X-direction center of each of conductive layers 14 from the projecting ends of IPD films and conductive layers 14.

The manufacturing process flow of capacitive elements Ca is substantially the same as the manufacturing process flow of resistive element Ra. Thus, mask pattern MK3 illustrated in FIG. 50B for example is formed instead of mask pattern MK2 illustrated in FIG. 46A. Mask pattern MK3 is formed so as to extend continuously above stacked structures G2 disposed in the X direction.

In each of capacitive elements Ca, tunnel insulating film 11 and IPD film 13 serving as insulating layers are disposed between silicon film 10 and conductive layer 14 serving as electrodes. Thus, capacitive elements Ca are formed in second layer L2 as well. The fourth embodiment was described through an example in which resistive elements Ra/capacitive elements Ca are formed in second layer L2. However, resistive elements Ra/capacitive elements Ca may be formed in third layer L3 or above.

In the fourth embodiment, resistive elements Ra and/or capacitive elements Ca are formed using dummy element regions Sa (stacked structures G and G2) in second layer L2 or above in peripheral-circuit region P. As a result, it is possible to reduce the circuit area since resistive elements Ra and/or capacitive elements Ca need not be provided in first layer L1.

### Fifth Embodiment

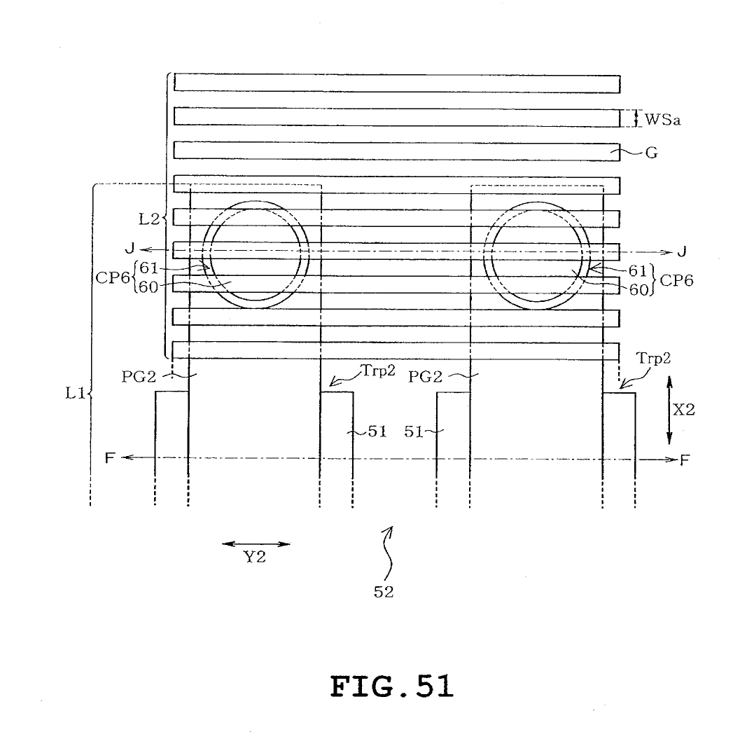

FIGS. 51 to 56 illustrate a fifth embodiment. The fifth embodiment is described through an example in which peripheral transistors Trp2 are formed in first layer L1, stacked gate structures G including element regions Sa are formed in second layer L2 above peripheral transistors Trp2.

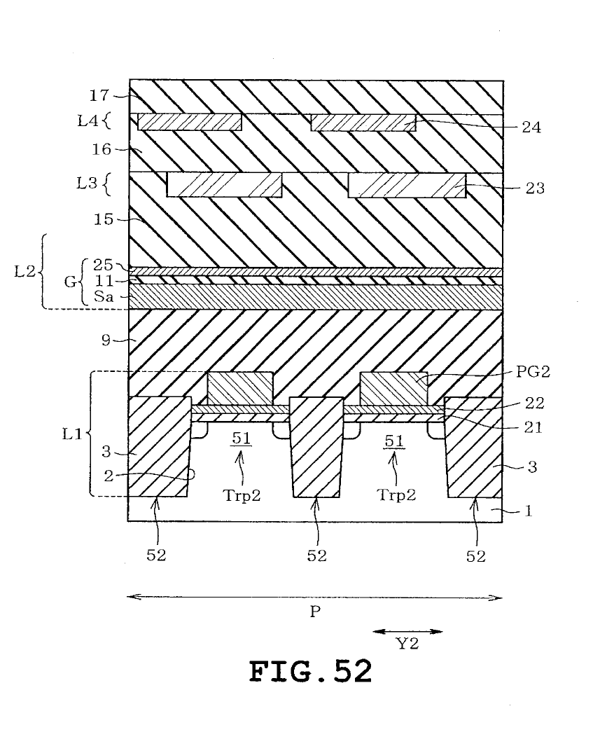

FIG. 51 provides one schematic example of a plan view and FIG. 52 provides one schematic example of a vertical cross-sectional view taken along line F-F of FIG. 51. Referring to FIG. 52, peripheral transistors Trp2 are formed in first layer L1. Peripheral transistors Trp2 serve as high-breakdown-voltage transistors.

In peripheral transistors Trp2, dimensions such as the X-direction widths and Y-directions widths of element regions Sa, thicknesses of tunnel insulating films 21, thicknesses and widths of gate electrodes PG2, and diameters of gate contacts CP6 are configured to be greater than the widths of the components (such as word lines WL, bit lines BL) of memory-cell region M in order to meet the ampacity.

In one example of a plan view illustrated in FIG. 51, gate electrodes PG2 of peripheral-circuit transistors Trp2 of first layer L1 extend in the X2 direction. Element regions 51 of first layer L1 are surrounded by element isolation regions 52 so as to be isolated like islands.

Gate electrode PG2 of first layer L1 extend in the X2 direction above and across element regions 51. Stacked structures G of second layer L2 having widths WSa extend in the Y2 direction. Dummy stacked structures G correspond to stacked structures G of second layer L2 described in the foregoing embodiments. Each of dummy stacked structures G has width WSa which is equal to width WSa of each of element regions Sa in memory-cell region M.

In first layer L1, gate electrodes PG2 project above element isolation regions 52. Gate contacts CP6 are formed above the ends of gate electrodes PG2. Gate contacts CP6 are disposed across stacked structures G. Two gate contacts CP6 adjacent in the Y2 direction are disposed so as to intersect with the same gate structures G. As illustrated in FIG. 52, interlayer insulating film 9 is formed above gate electrodes PG2 of first layer L1. Dummy stacked structures G of second layer L2 are formed above interlayer insulating film 9.

Dummy stacked structures G are formed of stacks of element regions Sa, tunnel insulating films 11, silicon films 25 serving as charge storing layer FG, or the like. Interlayer insulating film 15 is formed above dummy stacked structures G. Upper wirings 23 and 24 are formed in third layer L3, fourth layer L4, or the like disposed above interlayer insulating film 15.

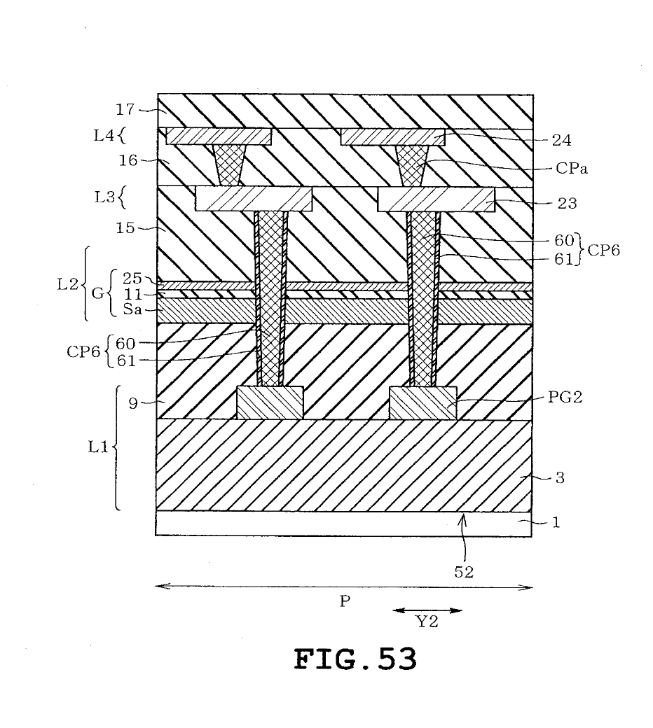

FIG. 53 is one schematic example of a cross section taken along line J-J of FIG. 51. As illustrated in FIG. 53, gate contacts CP6 extend through dummy stacked structures G of second layer L2 so as to structurally connect upper layer wirings 23 of third layer L3 with upper surfaces of gate electrodes PG2 of first layer L1. Further, upper layer wirings 23 of third layer L3 and upper layer wirings 24 of fourth layer L4 are connected by contacts CPa.

As illustrated in FIG. 53, each of gate contacts CP6 is provided with electrode material 60 and spacer film 61 formed along the outer side of electrode material 60. Examples of electrode material 60 are tungsten or polysilicon. Spacer film 61 is made of a silicon oxide film for example.

Spacer films 61 cover the sidewalls of electrode materials 60 so that electrode materials 60 and conductive materials of dummy stacked structures G of second layer L2 do not structurally contact each other. That is, it is possible to prevent electrical short circuiting of gate contacts CP6 adjacent in the Y2 direction by providing spacer films 61. Further, it is possible to maintain the insulation between gate contacts CP6 and dummy stacked structures G of second layer L2 by providing spacer films 61.

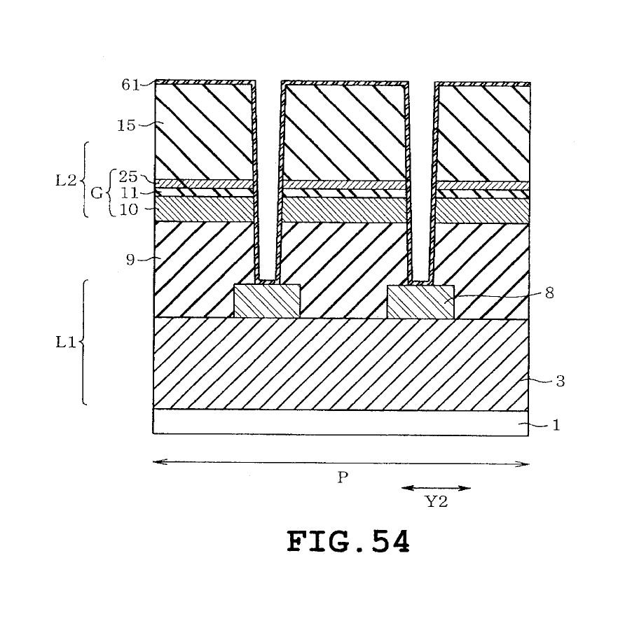

A brief description will be given on the manufacturing process flow of the above described structures, in particular, the manufacturing process flow of spacer films 61. The manufacturing process flow up to the formation of the structures in first layer L1 and in second layer L2 is the same as in the foregoing embodiments. Then, as illustrated in FIG. 54, interlayer insulating film 15 is formed of for example a silicon oxide film using CVD. Then, via holes are formed from third layer L3 to the upper surfaces of gate electrodes PG2 of first layer L1 by anisotropic etching or the like using RIE.

Then, the via holes are filled with spacer films 61, formed for example of silicon oxide films, by CVD and/or ALD. At this phase of the manufacturing process flow, spacer films 61 are formed along the bottom portions of the via holes.

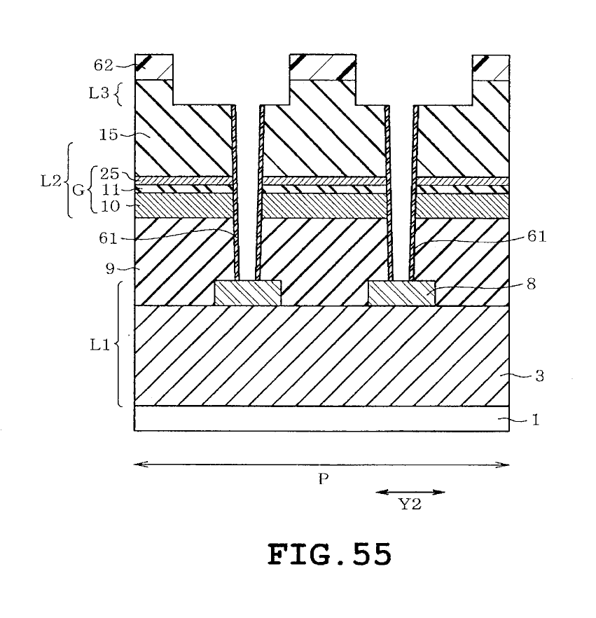

Referring to FIG. 55, mask pattern 62 is formed so as to form openings for forming upper layer wirings 23 of third layer L3 and anisotropic etching is carried out by RIE using mask pattern 62 as a mask.

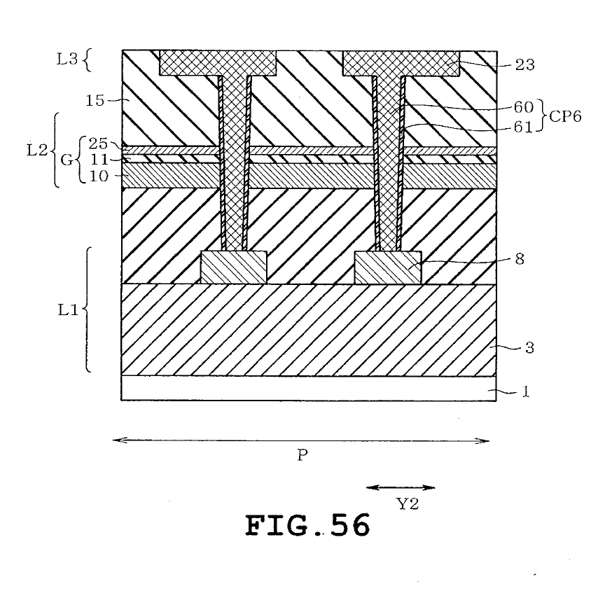

As a result, it is possible to form openings for forming upper wiring layers 23 of third layer L3 and to remove silicon oxide films formed along the bottom portions (immediately above gate electrodes PG) of the via holes. Thus, it is possible to leave silicon oxide films as spacer films 61 along the sidewalls of via holes. Referring to FIG. 56, electrode materials 60 are filled in via holes and the openings using CVD or the like.

As a result, it is possible to structurally contact upper layer wirings 23 of third layer L3 with gate electrodes PG2 of first layer L1. Further, electrode materials 60 do not contact dummy stacked structures G of second layer L2 and thus, it is possible to electrically isolate electrode materials 60 and dummy stacked structures G. Thus, it is possible to prevent short circuiting of gate contacts CP6 adjacent in the Y2 direction and improve the reliability of wiring connection of gate contacts CP6. Description will not be given on manufacturing process flow for forming upper layer wirings 24 disposed in a layer higher than third layer L3.

In the fifth embodiment, spacer films 61 are provided along the sidewalls of gate contacts CP6 extending through second layer L2. Thus, it is possible to prevent contact between dummy stacked structures G extending in second layer L2 and gate contacts CP6 and prevent short circuiting of the adjacent gate contacts CP6.

Further, it is possible to determine the layout of gate contacts CP6 independent of the widths WSa and layout of stacked structures G. As a result, it is possible to improve layout flexibility.

The fifth embodiment was described through an example in which high-breakdown-voltage transistors are used as peripheral transistors Trp2. In an alternative embodiment, it is possible to use low voltage (low-breakdown-voltage) transistors as peripheral transistors Trp2. It is possible to obtain similar effects in such alternative embodiment.

### Sixth Embodiment

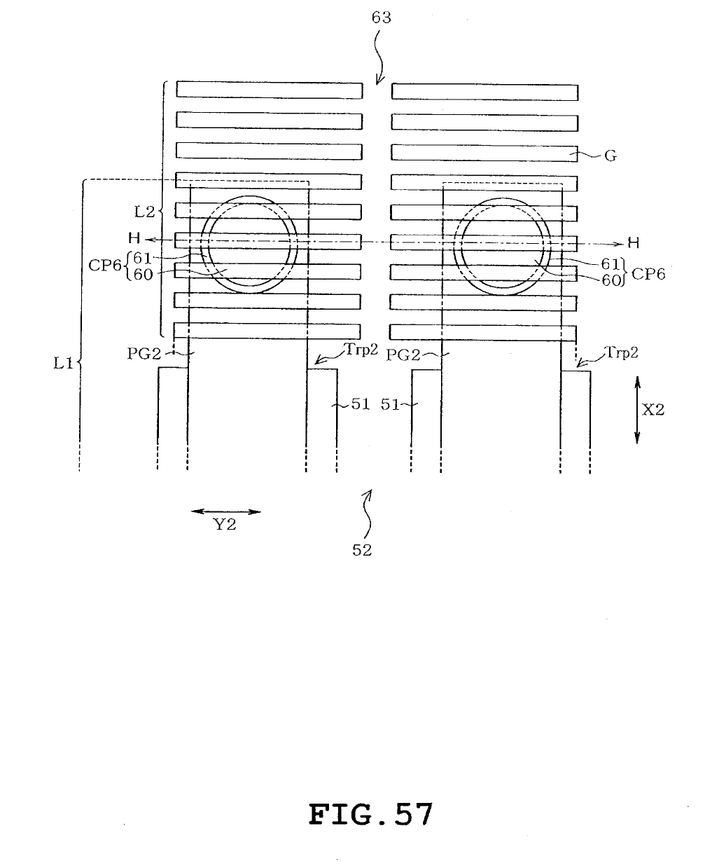

FIGS. 57 to 60 illustrate a sixth embodiment. The sixth embodiment is described through an example in which stacked structures G (element regions Sa) formed between gate contacts CP6 are divided. As described in the fifth embodiment, gate contacts CP6 are formed so as to extend through second layer L2.

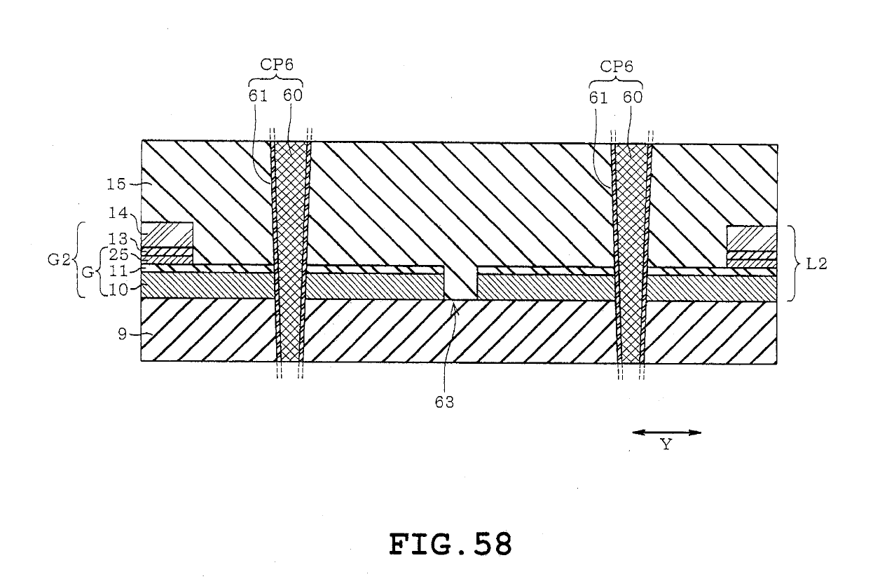

FIG. 57 is one schematic example of a plan view. FIG. 58 is one schematic example of structures of gate contacts CP6 extending through dummy stacked structures G of second layer L2. As illustrated in FIGS. 57 and 58, spacer films 61 are formed along the sidewalls of electrode materials 60 of gate contacts CP6 extending through second layer L2.

Still referring to FIGS. 57 and 58, dummy stacked structures G (especially silicon films 10) in second layer L2 are divided in the Y2 direction (see dividing region 63 in FIGS. 57 and 58, respectively). Interlayer insulating film 16 is filled in dividing region 63. As a result, it is possible to improve the insulation between adjacent gate contacts CP6.

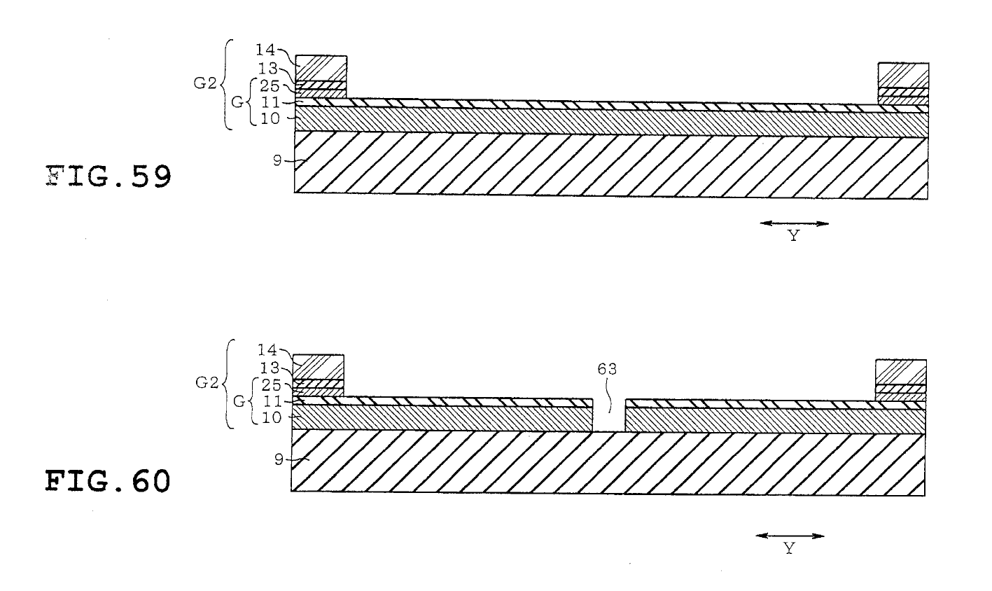

A brief description will be given on the manufacturing process flow of the above described structures. Silicon film 10, tunnel insulating film 11, silicon film 25, IPD film 13, and conductive layer 14 are formed as illustrated in FIG. 59. Then, conductive layer 14, IPD film 13, and silicon film 25 are removed, by anisotropic etching using tunnel insulating film 11 as a stopper, from the region in which gate contacts CP6 are formed.

Then, as illustrated in FIG. 60, dividing region 63 is formed by forming a trench into tunnel insulating film 11 and silicon film 10 located near the central portion of the region where conductive layer 14, IPD film 13, and silicon film 25 are removed. Referring to now to FIG. 58, interlayer insulating film 15 is formed by CVD so as to fill dividing region 63.

Then, as described in the fifth embodiment, via holes are formed through interlayer insulating film 16, dummy stacked structure G, and interlayer insulating film 9 and gate contacts CP6 having spacer films 61 are formed in the via holes. Thus, it is possible to provide dividing region 63 in element regions Sa (dummy stacked structures G) disposed between the adjacent gate contacts CP6 and thereby further improve the insulation.

High voltage is applied particularly to gate contacts CP6 connected to high-breakdown-voltage transistors. As a result, providing only spacer films 61 may not achieve sufficient insulation breakdown voltage. It is possible to improve the insulation breakdown voltage between gate contacts CP6 by forming dividing region 63 in addition to spacer films 61. It is possible to maintain good insulation with only dividing region 63 depending upon the voltage level applied to the contacts. In such case, it is possible to omit spacer films 61.

### Seventh Embodiment

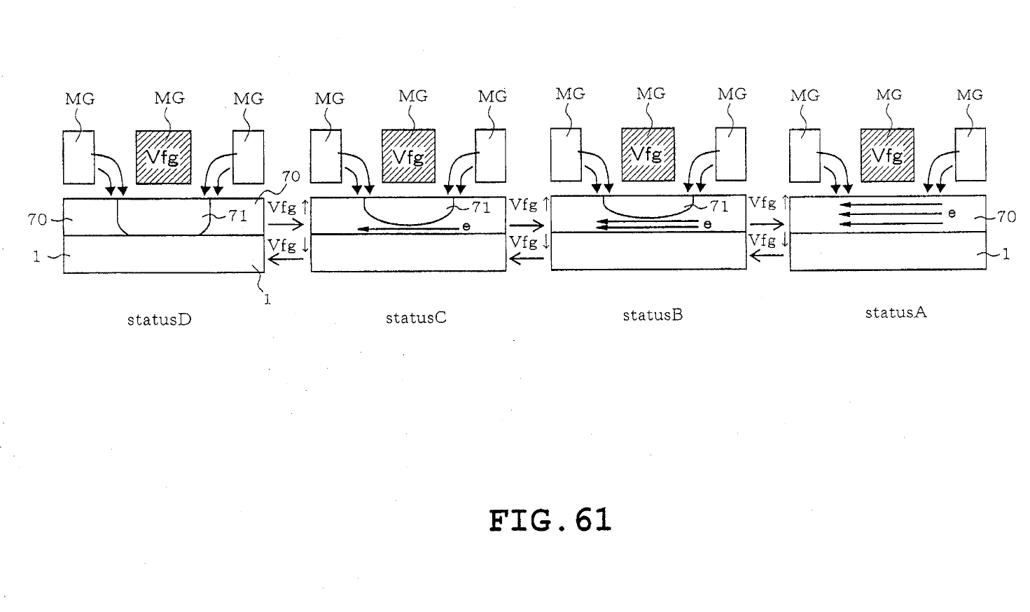

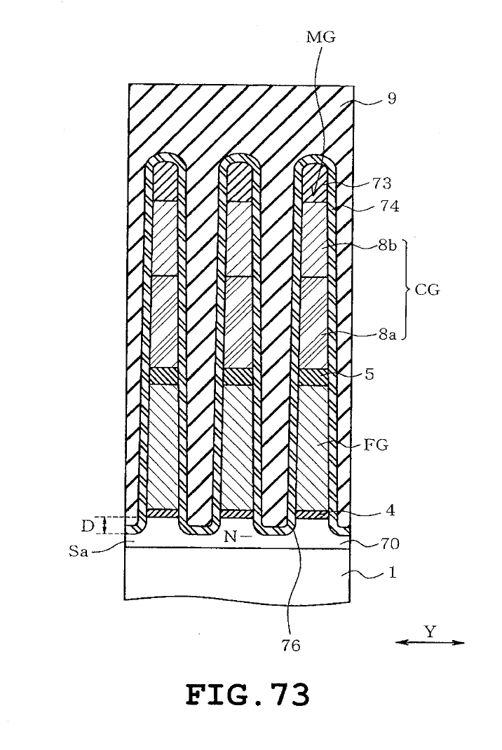

FIGS. 61 to 73 illustrate a seventh embodiment. In a P type semiconductor substrate 1 for example, enhancement-type memory-cell transistors Trm are formed most of the time.

In enhancement-type memory-cell transistors Trm, gate electrodes MG are formed above semiconductor substrate 1 via tunnel insulating films and source/drain diffusion layers doped with N type impurities are formed in both sides of gate electrodes MG. The channel length in such structure relies on the distance between the N type diffusion layers and thus, the effective channel length becomes shorter as the gate length becomes shorter.

In recent years, the effect of short channel effect is becoming unignorable with advances in shrinking of design rules and cells. Phenomenon such as reduced neutral threshold voltage and degraded S-factor occur when affected by short channel effect.

In the seventh embodiment, depletion type memory-cell transistors Trm are provided in order to suppress the short channel effect and increase the effective channel length. More specifically, the depletion-type memory-cell transistors Trm of the seventh embodiment are provided with N-layers (N minus layers) in the element regions without forming high-concentration diffusion layers in the source/drain regions. It is possible to cutoff depletion-type memory-cell transistors Trm by increasing the depths of depletion layers.

The channel structure of depletion-type memory-cell transistor Trm differs from the channel structure of enhancement-mode memory-cell transistor. Thus, the principle of “short channel effect” in a narrower sense may not be applicable to depletion-type memory-cell transistor Trm. However, in a broader sense, the term “short channel effect” may be considered to mean that the threshold value is reduced as the channel length becomes shorter. Thus, the term “short channel effect” in the broader sense will be used in the seventh embodiment.

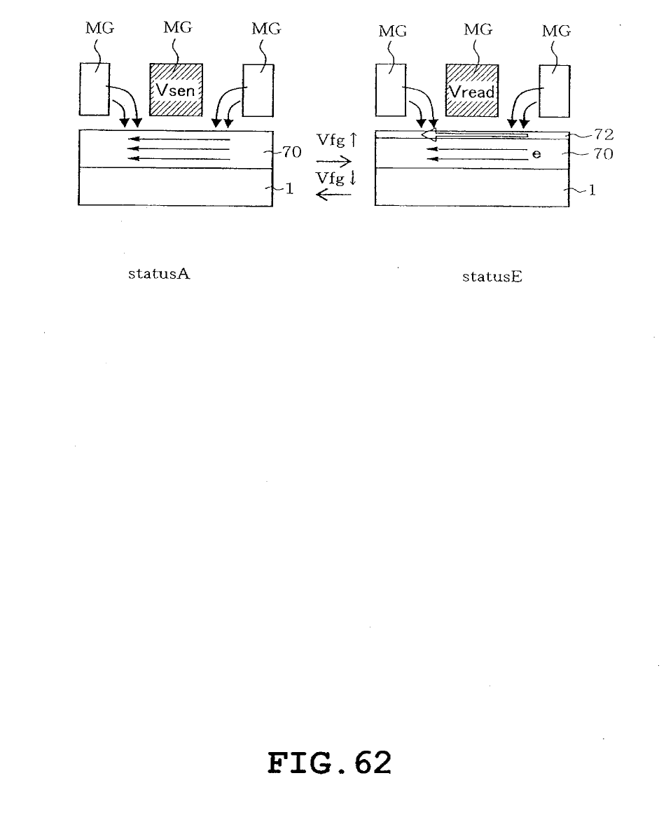

FIGS. 61 and 62 are examples of descriptive views for schematically describing the structural principles. As illustrated in FIG. 61, in depletion-type memory-cell transistors Trm, N-layer 70 (corresponding to N type impurity doping layer) is formed in the surface layer of P type semiconductor substrate 1. As a result, current flows through N-layer 70 as indicated in “status A” indicating a normally-ON state even when 0V is applied to gate electrode MG (corresponding to memory-cell gate electrode) by control circuit CC.

As illustrated in “status B” to “status D” of FIG. 61, N-layer 70 immediately below gate electrodes MG are depleted and the transistors are cutoff (refer to the regions identified as depletion layers 71) when control circuit CC applies negative voltage (Vfg decrease) to gate electrodes MG via word line WL. Stated differently, N-neutral region 70 increases/decreases with increase/decrease of the region of depletion layer 71. This operation mode will be referred to as the depletion-mode. Control circuit CC may apply positive voltage to source lines SL or semiconductor substrate 1 instead of applying negative voltage to gate electrodes MG.

Referring to FIG. 62, when control circuit CC applies positive voltage (Vfg increase) to gate electrode MG in “status A”, accumulation layer 72 is formed in the surface layer of semiconductor substrate 1 as indicated in status E. This state is referred to as the accumulation mode.

In the accumulation mode, accumulation layer 72 in the surface layer of semiconductor substrate 1 serves as the current path. More specifically, the accumulation mode is an operation mode in which control circuit CC applies positive voltage on gate electrode MG to generate accumulation layer 72 and thereby causing current flow through accumulation layer 72.

In the depletion mode, it is possible to increase the effective channel length since the transistor is cutoff by the spreading of depletion layer 71 to N-layer 70 beside gate electrode MG. In the accumulation mode on the other hand, accumulation layer 72 is formed in the regions beside gate electrode MG by fringe field originating from the target cell and the adjacent cells to form current path in accumulation layer 72. As a result, it is possible to increase the effective channel length without providing the diffusion regions as was the case in the enhancement-type transistors.

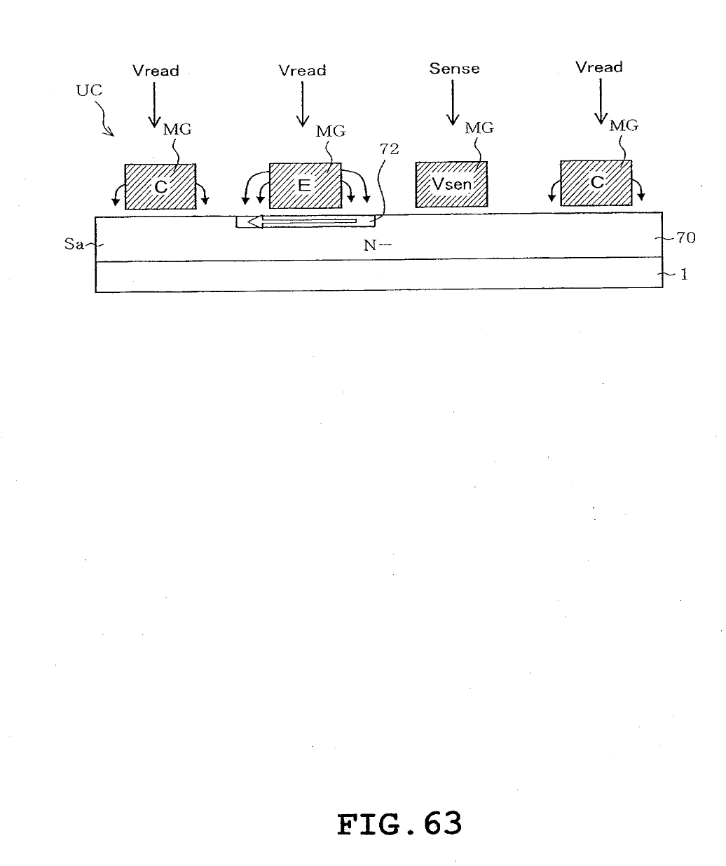

FIG. 63 is a descriptive view. The symbols “E”, “A”, “B”, and “C” indicated in gate electrodes MG in the figures beyond FIG. 63 represent the data storage level corresponding to charge amount in charge storage layer FG. The threshold voltages of the data storage levels are specified in the order of erased state (E)<programmed state (A)<programmed state (B)<programmed state (C) in each memory-cell transistor Trm.

For example, the operation of a given cell unit UC is considered with reference to FIG. 63. In this cell unit UC, the threshold voltage of each memory-cell transistor Trm is determined based on the charge amount (electron amount) accumulated in charge storing layer FG. The threshold voltage distribution in each memory-cell transistor Trm is determined based on the storage data of the cell.

When memory-cell transistors Trm are series connected as indicated in the seventh embodiment, it is required for the read-target memory cell to be properly readable regardless of whether the adjacent cell is in the erased state or the programmed state.

For example, as illustrated in FIG. 63, it is required for the status of read-target memory cell (identified as “Sense” in FIG. 63) to be readable regardless of whether the adjacent cell is in the erased state (E) or the programmed state (C). Suppose that the adjacent cell is in either “status A” or “status E”.

When memory-cell transistor Trm is in the programmed state (C), fringe field is weak since the amount of accumulated electrons in floating electrode layer FG is large. As a result, it is difficult for accumulation layer 72 to form. On the other hand, when memory-cell transistor Trm is in the erased state (E), fringe field is strong since the amount of accumulated electrons in floating electrode layer FG is small. As a result, accumulation layer 72 forms easily immediately below or beside the read-target cell.

As a result, the amount of current flowing in element regions Sa (element active region) varies depending upon the difference in the count of majority carrier (e) in accumulation layer 72 and the count of carrier in N-neutral region 70. In other words, current path and amount of current vary depending upon whether the adjacent cell is in the erased state (E) or the programmed state (C). Thus, variation occurs in the cell current which leads to a possibility of reading error.

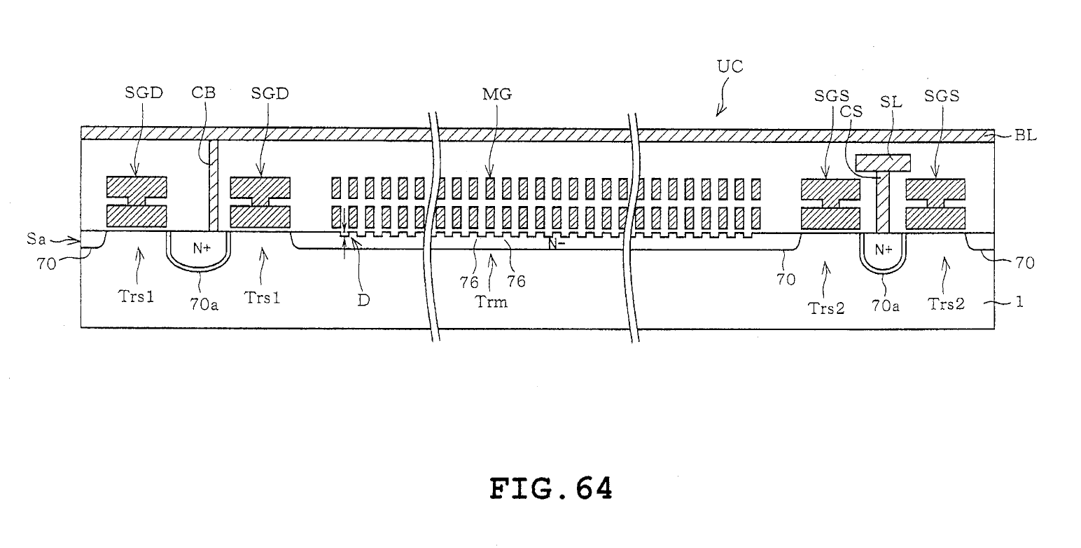

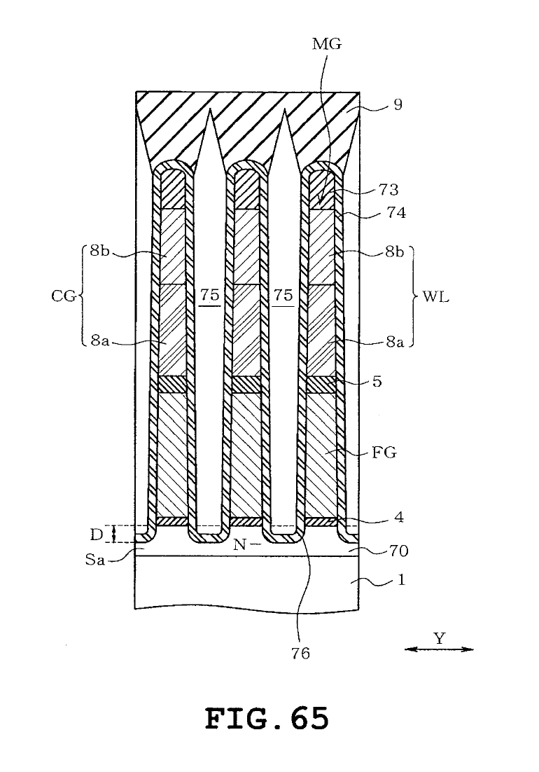

Thus the structures illustrated in FIGS. 64 and 65 are adopted in the seventh embodiment. A description will be given on the vertical cross-sectional structure of the seventh embodiment with reference to FIG. 64 schematically illustrating one example of a cross-sectional structure of a cell unit and FIG. 65 schematically illustrating one example of a vertical cross-sectional structure of a memory-cell transistor. A P type monocrystal silicon may be used as semiconductor substrate 1. As schematically illustrated in the cross sections taken along element region Sa in FIGS. 64 and 65, N-layers 70 are provided in the surface layer of element region Sa of semiconductor substrate 1.

As illustrated in FIG. 64, N-layer 70 is provided in a continuous manner between select transistors Trs1 and Trs2. The depths of N-layer 70 are substantially constant throughout the region below gate electrodes MG of memory-cell transistors Trm.

P type impurity doping regions serving as channel regions are provided immediately below each of select gate electrodes SGD of select transistor Trs1 and select gate electrodes SGS of select transistor Trs2. N type impurity diffusion region 70a taking DDD structure is provided immediately below bit-line contact CB and source-line contact CS, respectively.

FIG. 65 schematically illustrates one example of a cross sectional view of memory-cell transistors Trm. Memory-cell transistors Trm are provided with gate electrodes MG. Each of gate electrodes MG is provided with charge storing layer FG formed above N-layer 70 of semiconductor substrate 1 via tunnel insulating film 4, IPD film 5 formed above charge storing layer FG, and control electrode CG formed above IPD film 5.

Control electrode CG is provided with conductive layer 8. Conductive layer 8 is provided with polycrystalline silicon film 8a doped with impurities such as phosphorous and low-resistance metal layer 8b such as a tungsten layer stacked above polysilicon film 8a. The structure of gate electrode MG is substantially the same as in the structure of memory-cell transistor Trm described in the foregoing embodiments. The seventh embodiment, however, is described through an example in which cap films 73 are formed above control electrodes CG. Cap films 73 are formed of a silicon nitride film for example.

Further, silicon oxide film 74 serving as a protection film is formed along the upper surfaces of cap films 73 and along the sidewalls of cap films 73 and gate electrodes MG. In the seventh embodiment, gaps 75 are provided between silicon oxide film 74 covering gate electrodes MG. Gaps 75 are provided for suppressing the parasitic capacitance between gate electrodes MG of memory-cell transistors Trm.

In the seventh embodiment, trenches 76 are formed in the surface layer of N-layer 70 of semiconductor substrate 1 located in both sides of gate electrodes MG of memory-cell transistors Trm. Steps D descending from the upper surfaces of semiconductor substrate 1 result in the surface layer of N-layer 70 by the formation of trenches 76. Steps D are provided in the surface layer of N-layer 70 for suppressing the effect of fringe field.

Gaps 75 are located between each of gate electrodes MG and extend upward above each of gate electrodes MG. Interlayer insulating film 9 extends across silicon oxide film 74 so as to cover gaps 75. Interlayer insulating film 9 is formed above the top upper surfaces of silicon oxide film 74. Gaps 75 protrude upward above cap films 73 and gate electrodes MG. Interlayer insulating film 9 covers the edges of the protrusions of gaps 75.

Air gaps 75 located between each of gate electrodes MG and also extend downward below the under surfaces of tunnel insulating films 4. Thus, the lower ends of gaps 75 are located below the upper surfaces of semiconductor substrate 1. The fringe fields generated by gate electrode MGs are applied from the sidewalls and lower side ends of charge storing layers FG and affects the surface layers of semiconductor substrate 1 located in both sides of gate electrodes MG.

In the seventh embodiment, the lower ends of gaps 75 between gate electrodes MG are located below the upper surfaces of semiconductor substrate 1. Thus, it is possible to reduce the relative dielectric constants of such spaces below the upper surfaces of semiconductor substrate 1 and further reduce the effect of fringe fields on N-layer 70.

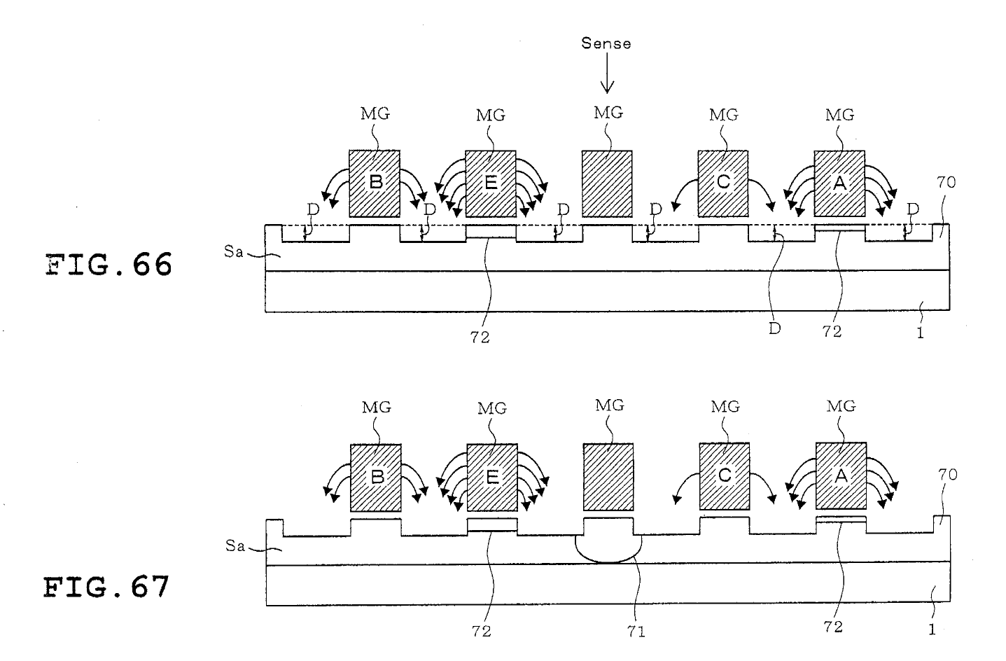

FIG. 66 is a descriptive view schematically illustrating the advantages of the structures of the seventh embodiment. In the seventh embodiment, steps D are provided in the upper portion of N-layer 70 located between each of gate electrodes MG. Thus, current flows mostly below steps D.

Further, the intensity of fringe field generated by charge storing layer FG of each memory-cell transistor Trm varies depending upon the amount of charge injected into charge storing layer FG. However, fringe field is relaxed when the structures of the seventh embodiment are adopted. The reasons for this phenomenon will be later described in detail.

As a result, each of memory-cell transistors Trm can be operated substantially in the depletion mode regardless of the charge storing states of charge storing layers FG of memory-cell transistors Trm. When the structures of the seventh embodiment are adopted, current flowing through N-layer 70 can be made substantially constant even when the amounts of charge injected into gate electrodes MG of memory-cell transistors Trm vary.

As described earlier, depletion-type memory-cell transistors Trm cutoff the conducting current of cell unit UC by the formation of depletion layers 71. Thus, the thicknesses of N-layer 70 need not be thicker than the thicknesses of depletion layers 71 formed.

When constant electric field is applied, depletion layers 71 become narrower as the N type impurity concentrations of the channels become higher. The majority carrier decreases and thus, electron mobility decreases as the N type impurity concentration becomes lower. As a result, it becomes difficult for cell current to flow.

When the impurity concentration of N-layer 70 is 5×10¹⁷ [m⁻³] for example, it is possible to configure the maximum depth of depletion layer 71 to 70 [nm] for example depending upon the charge accumulation status of charge storing layer FG and the level of voltage applied to control electrode CG. The term “depth” indicates the depth from the surface of semiconductor substrate 1 located immediately below gate electrode MG.

For example, when the depth of N-layer 70 is 50 [nm] and the etching amount (the size of step D) is 10 [nm], the thickness of N-layer 70 is 40 [nm] and as a result, cell current is reduced by approximately 20%. If approximately 20% reduction of cell current is permissible, the upper limit of etching amount may be specified to approximately 10 [nm].

FIGS. 67 to 69 schematically illustrate the operation of memory-cell transistors Trm when control circuit CC varies the voltages applied to word lines WL (control electrode CG). A description will be given based on an example in which the target memory-cell transistor Trm is in the programmed state (A). Referring to FIG. 67, when the voltage applied to control electrode CG is Vsen1, depletion layer 71 extends to the lower end of N-layer 70 and current is cutoff.

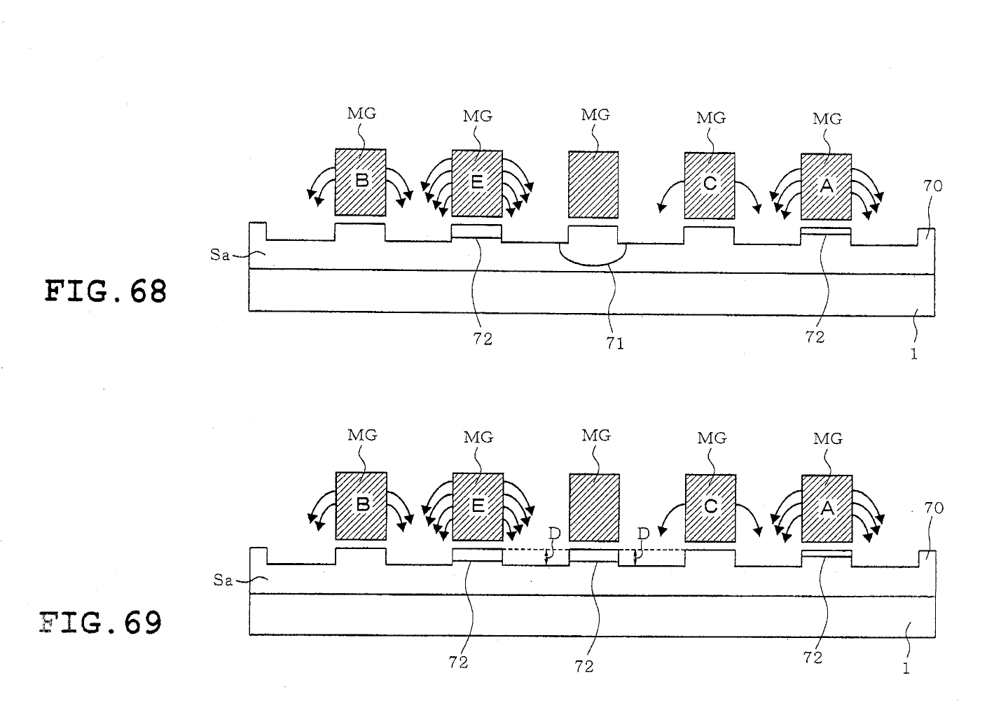

Further, as indicated in FIG. 68, when the voltage applied to control electrode CG is Vsen2 (>Vsen1), depletion layer 71 retracts toward the surface layer of N-layer 70 and current flows through N-layer 70.

That is, control circuit CC makes a judgment that the target memory-cell transistor Trm is in the programmed state (A) when the cell current does not flow when voltage Vsen1 is applied and the cell current flows when voltage Vsen2 is applied.

Further, as illustrated in FIG. 69, accumulation layer 72 is formed near tunnel insulating film 4 when voltage Vsen3 is applied to control electrode CG (Vsen3>threshold voltage Vth of memory-cell transistor Trm>Vsen2). However, because step D is formed in the surface layer of semiconductor substrate 1, accumulation layer 72 does not extend to N-layer 70 located below step D. Thus, accumulation layer 72 formed in the accumulation mode does not affect the amount of current flowing in N-layer 70. As a result, it is possible to make the current flowing in N-layer 70 substantially constant even when the amount of charge injected into charge storing layer FG varies. It is thus possible to ensure stable operation.

In the seventh embodiment, trenches 76 (steps D) are provided in the upper portions of semiconductor substrate 1 located beside gate electrodes MG. Thus, it is possible to reduce the influence of fringe fields on N-layer 70. Further, gaps 75 are provided in the portions where steps D are formed. As a result, it is possible to reduce relative dielectric constants in such portions and further reduce the influence of fringe fields on N-layer 70.

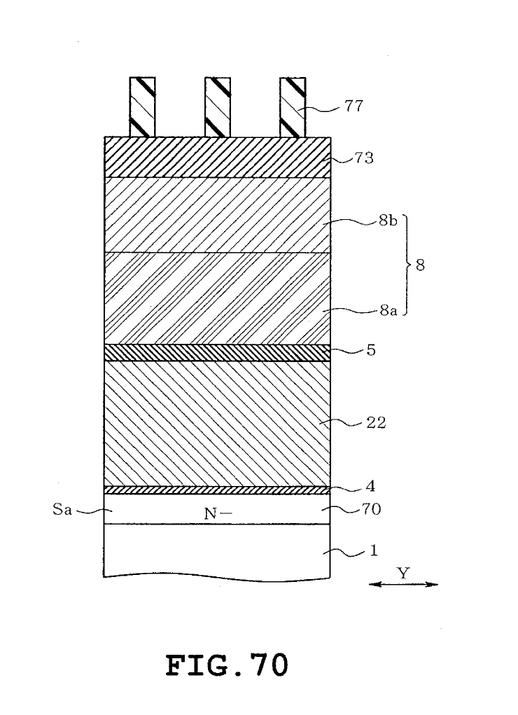

One example of a manufacturing process flow of the seventh embodiment will be described with reference to FIGS. 70 to 72. FIGS. 70 to 72 each schematically illustrates one phase of the manufacturing process flow of cross-sectional structures of memory-cell transistors Trm illustrated in FIG. 65. Detailed description will be given only on the main portions of the manufacturing process flow. Thus, the manufacturing process flow up to the cross-sectional structures illustrated in FIG. 70 will be described only briefly.

First, a P type monocrystal silicon substrate serving as semiconductor substrate 1 is prepared. N-layer 70 is formed in the surface layer of semiconductor substrate 1 in memory-cell region M. N-layer 70 is formed by introducing N type impurities such as arsenic (As) into the surface layer of P type semiconductor substrate 1 by techniques such as ion implantation and activating the introduced impurities. Alternatively, N-layer 70 may be formed by crystallizing amorphous silicon (a-Si) doped with N type impurities.

Then, tunnel insulating film 4 is formed above the surface of semiconductor substrate 1. For example, tunnel insulating film 4 may be a silicon oxide film formed by thermal oxidation. Tunnel insulating film 4 serves as tunnel insulating film (gate insulating film) of for each of memory-cell transistors Trm. Conductive layer 22 is formed above tunnel insulating film 4. Conductive layer 22 may be formed of a polysilicon film deposited by CVD or the like. The polysilicon film is doped with impurities such as phosphorous. A mask pattern is formed above conductive layer 22 and element isolation trenches 2 are formed along the Y direction so as to extend into conductive layer 22, tunnel insulating film 4, and the upper portion of semiconductor substrate 1.

Then, element isolation trenches 2 are filled with element isolation film 3. The upper portion of element isolation film 3 is planarized and etched back to expose the upper surfaces of conductive layers 22. Then, IPD film 5 is formed along the upper surfaces of conductive layers 22 and the upper surfaces of element isolation films 3. Element isolation trenches 2 and element isolation films 3 are not illustrated in the structures illustrated in FIGS. 65 and 70. However, the cross-sectional structures of element isolation trenches 2 and element isolation films 3 are similar to those formed in memory-cell region M illustrated in FIG. 4.

Silicon film 8a is formed above IPD film 5 by CVD for example and low-resistance metal layer 8b such as tungsten (W) is formed above silicon film 8a. Then, silicon nitride film serving as cap film 73 is formed by CVD for example above low-resistance metal layer 8b. Then, resist 77 is coated above cap film 73 to obtain the structure illustrated in FIG. 70.

Resist 77 serves as a mask pattern for forming select gate lines SGL1 and SGL2 and word lines WL along the X direction (word line direction).

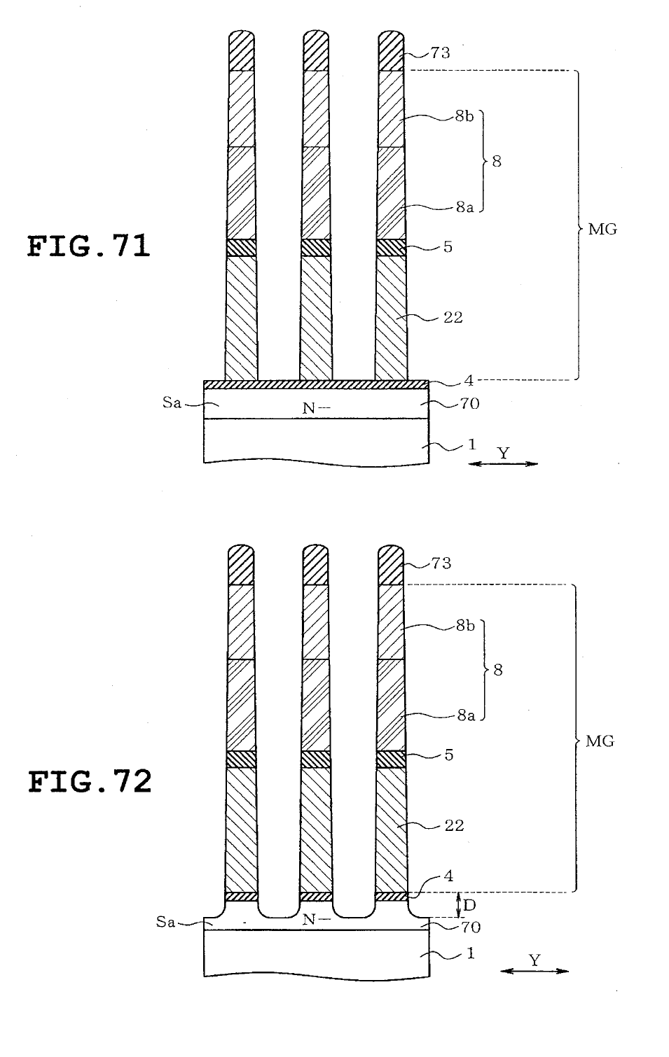

Referring to FIG. 71, cap film 73 is anisotropically etched by RIE using mask pattern formed of resist 77 as a mask. Resist 77 is thereafter removed. Then, low-resistance metal layer 8b, silicon film 8a, IPD film 5, and conductive layer 22 are anisotropically etched using cap films 73 as a mask.

In the seventh embodiment, the anisotropic etching is temporarily stopped on the upper surface of semiconductor substrate 1. Then, the surface layer of semiconductor substrate 1 is thereafter etched. Thus, it is possible to anisotropically etch low-resistance metal layer 8b, silicon film 8a, IPD film 5, and conductive layer 22 using the surface of semiconductor substrate 1 as a stopper. As a result, it is possible to form word lines WL, IPD films 5, and charge storing layers FG.

The aforementioned anisotropic etching may be performed using the upper surface of tunnel insulating film 4 as an etching stopper.

Referring to FIG. 72, the etching conditions are modified and the surfaces of semiconductor substrate 1 are slightly etched anisotropically. The depth of etching of semiconductor substrate 1 (step D) ranges approximately from 5 [nm] to 10 [nm] for example.

Etching is temporarily stopped on the upper surface of semiconductor substrate 1 (or the upper surface of tunnel insulating film 4) for surface alignment. Small amount of etching is further carried out thereafter. Thus, it is possible to make the precisions of etching depths of steps D uniform without degrading electrical performance.

The lower limit of etching amount of semiconductor substrate 1 is configured to the depth of accumulation layer 72 generated in N-layer 70 and the upper limit is configured to the depth of N-layer 70. The depth of accumulation layer 72 is determined by the thickness of accumulation layer 72 formed when reading voltage Vread is applied to memory-cell transistor Trm of erasing state (E).

When anisotropically etching semiconductor substrate 1, etching may be carried out in the amount to exceed the depth of accumulation layer 72 being generated when control circuit CC applies reading voltage Vread to control electrode CG of memory-cell transistor Trm in the erased state (E) which is not targeted for reading.

As a result, it is possible to make it difficult for accumulation layer 72, being generated when control circuit CC applies read voltage Vread to control electrode CG, to influence the flow of electrons (current flow) generated in N-layer 70. For example, when the depth of accumulation layer 72 is less than 5 [nm], the amount of etching is preferably configured to 5 [nm] or greater when variation of etching depth is taken into consideration.

The upper limit of etching amount is configured to the depth of N-layer 70 in order to prevent N-layer 70 from being divided.

The division of N-layer 70 needs to be prevented because the amount of conductible current is determined by the depth obtained by subtracting the etching depth from the depth of N-layer 70. The upper limit of anisotropic etching may be determined to an amount that would allow the flow of maximum channel current of cell unit UC. Gate electrodes MG may be formed above semiconductor substrate 1 via tunnel insulating films 4 in the above described manner.

After dividing gate electrodes MG, P type impurities are introduced into N-layer 70 serving as channel regions of select transistors Trs1 and Trs2 as illustrated in FIG. 64. P type impurities are introduced at an angle into the surfaces of semiconductor substrate 1 through gaps 75 between select gate electrodes SGD/SGS and gate electrodes MG of memory-cell transistors Trm.

Thus, it is possible to introduce P type impurities into the regions immediately below select gate electrodes SGD/SGS of select transistors Trs1/Trs2. The impurities are activated by thermal treatment performed later in the manufacturing process flow (See the regions located immediately below select gate electrodes SGD and SGS of FIG. 64).

Then, as illustrated in FIG. 65, a thin silicon oxide film 74 is formed along the upper surfaces and sidewalls of cap films 73, and the sidewalls of each of gate electrodes MG by CVD or the like. Silicon oxide film 74 is formed to ensure reliability.

Then, interlayer insulating film 9 is formed for example by plasma CVD so as to provide gaps 75 between each of gate electrodes MG. N type impurities are doped first in low concentration and then in high concentration into the regions immediately below bit-line contacts CB and source-line contacts CS. The impurities are activated by thermal treatment. Thus, it is possible to form N type impurity diffusion region 70a taking a DDD structure.

The manufacturing process flow for subsequent formation of bit-line contacts CB, source-line contacts CS, and bit lines BL as well as for upper layer wirings will not be described.

According to the manufacturing process flow of the seventh embodiment, steps D are provided in the upper portions of semiconductor substrate 1 located beside gate electrodes MG and interlayer insulating film 9 is formed so as to provide gaps 75 in the regions where steps D are provided. As a result, it is possible to relax the influence of fringe field more effectively.

Further, when dividing gate electrodes MG by anisotropically etching stack of films 4, 22, 5, 8a, and 8b, the upper surfaces of semiconductor substrate 1 (or tunnel insulating films 4) are used as stoppers for temporarily stopping the etching. Then, upper portions of semiconductor substrate 1 are etched anistropically after modifying the etching conditions. As a result, it is possible to uniform the steps beside gate electrodes MG and evenly relax the influence of fringe field.

It is possible to relax the influence of fringe field without providing gaps 75. Thus, it is not required to provide gaps 75. Instead, when depositing interlayer insulating film 9, the gaps between gate electrodes MG may be filled with interlayer insulating film 9 formed of for example a silicon oxide film by LPCVD or the like.

### Eighth Embodiment

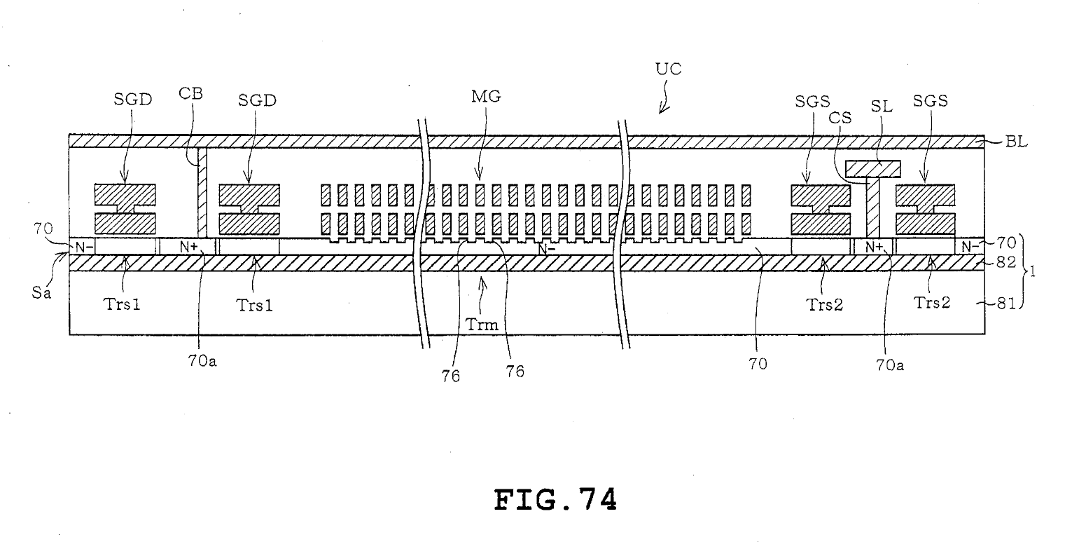

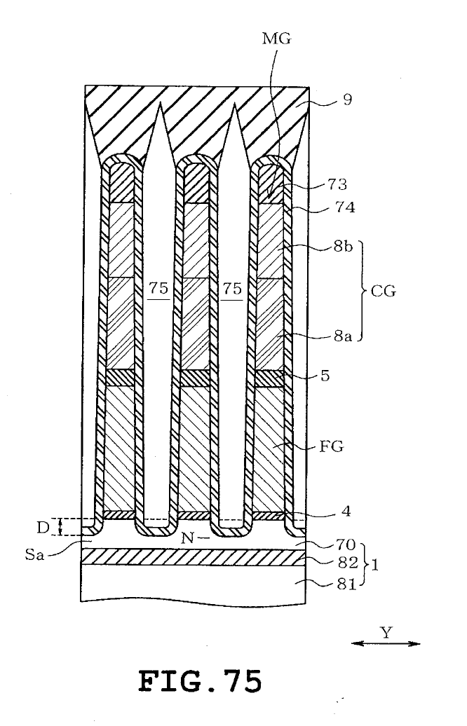

FIGS. 74 and 75 illustrate an eighth embodiment. In the eighth embodiment, insulating film (such as silicon oxide (SiO₂) film) 82 is disposed between N-layer 70 and P type layer 81 of P type semiconductor substrate 81.

FIG. 74 illustrates the entire structure of a cell unit. FIG. 75 schematically illustrates a cross-sectional view of some of memory-cell transistors Trm. As illustrated in FIGS. 74 and 75, insulating film 82 is disposed between P type layer 81 of P type semiconductor substrate 1 and N-layer 70. The structure takes the so-called SOI (Silicon On Insulator) and thus, possess a back bias function. It is possible to control the extension of depletion layer 71 described in the seventh embodiment by configuring control circuit CC to apply backward bias to P type layer 81.

Further, by forming insulating film 82 using SOI technique before implanting ions into N-layer 70 by ion implantation for example and thereafter thermally treating the implanted ions, it is possible to suppress diffusion of N type impurities toward P type layer 81.

Further, it is possible to establish contact between lower limit portion of the depletion layer formed in N-layer 70 with insulating film 82. As a result, it is possible to improve the cutoff properties of memory-cell transistor Trm.

### Ninth Embodiment

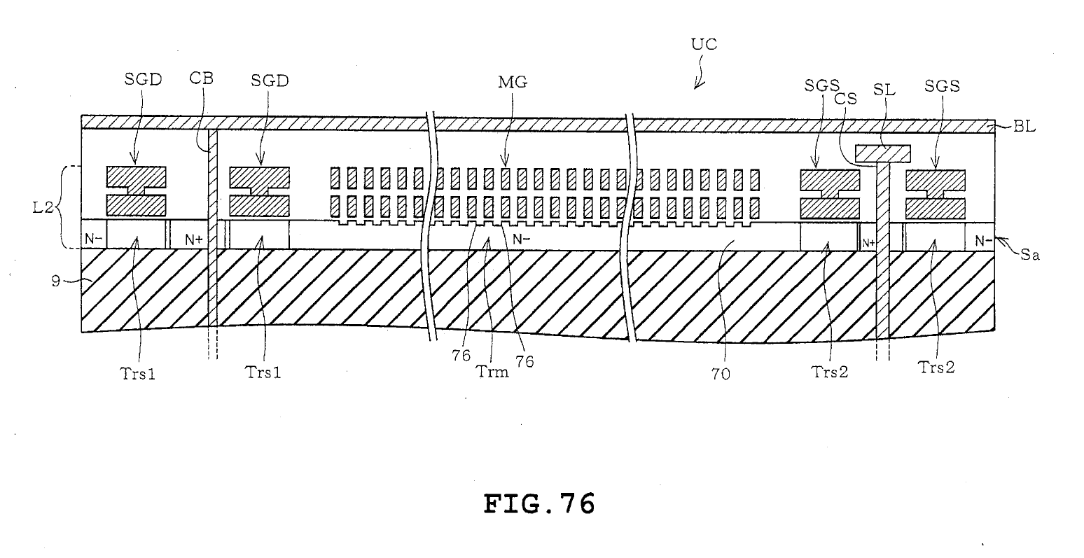

FIG. 76 illustrates a ninth embodiment. In the ninth embodiment, the element regions of N-layer 70 described in the foregoing embodiments are preferably formed in second layer L2 illustrated in FIG. 76 or layers above second layer L2 that constitute cell unit UC.

In the ninth embodiment, interlayer insulating film 9 illustrated in FIG. 76 corresponds to insulating film 82 of the eighth embodiment. Because interlayer insulating film 9 above first layer L1 serves as a buried insulating film, there is no need to form a buried insulating film.

Further, element regions Sa located in second layer L2 or above are formed of for example polysilicon film 10 as described in the first embodiment. N-layer 70 may be formed by introducing N type impurities into polysilicon film 10.

In the ninth embodiment, it is possible to improve the properties of memory-cell transistors Trm in second layer L2. Especially because element regions Sa of memory-cell transistors Trm in second layer L2 are mostly formed of polysilicon, large variation is observed in cell current. However, by adopting the structures of the ninth embodiment, it is possible to improve the properties of memory-cell transistors Trm in second layer L2. Further, it is possible to combine the ninth embodiment with the first to sixth embodiments.

### Other Embodiments

The following modifications may be made to the embodiments described above.

In the examples described in the first to fifth embodiments, element regions Sa of first layer L1 and element regions Sa of second layer L2 were configured to extend in the same direction. Alternatively, element regions Sa of first layer L1 may be configured to cross or be orthogonal to element regions Sa of second layer L2.

In each of the foregoing embodiments, gate electrodes MG of memory-cell transistors Trm may be configured as the so-called protruding gate electrodes in which conductive layers 22 protrude from the upper surfaces of element isolation films 3. Alternatively, gate electrodes MG of memory-cell transistors Trm may be configured as the so-called flat gate electrodes in which conductive layers 22 are substantially coplanar with the upper surfaces of element isolation films 3.

In the foregoing embodiments, memory-cell array Ar is configured as a single structure. Alternatively, memory-cell array Ar may be divided into regions (planes).

In each cell unit UC, one dummy cell may be provided in select transistor Trs1 side (drain side) and in select transistor Trs2 side (source side), respectively. Two or more dummy cells may be provided alternatively.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A nonvolatile semiconductor storage device comprising:
a memory-cell region;
a peripheral-circuit region disposed adjacent to the memory-cell region;
a first memory-cell unit disposed in a first layer located in the memory-cell region;
a second memory-cell unit disposed in a k-th layer of the memory-cell region where k is an integer equal to or greater than 2, the second memory-cell unit having an element region extending in a first direction and having a first width in a second direction crossing the first direction; and
a peripheral-circuit element disposed in the first layer located in the peripheral-circuit region;
wherein two or more dummy elements each having a second width 2n+1 times greater than the first width in the second direction are disposed in the k-th layer located in the peripheral-circuit region where n is an integer equal to or greater than 0.

2. The device according to claim 1, wherein at least one of the dummy elements serves as a resistor of a resistive element.

3. The device according to claim 2, wherein contacts being spaced from one another are provided above the resistor.

4. The device according to claim 1, wherein at least one of the dummy elements serves as an electrode of a capacitive element.

5. The device according to claim 4, wherein the capacitive element is provided with a stacked structure having the electrode, a tunnel insulating film disposed above the electrode, a silicon film disposed above the tunnel insulating film, an interpoly dielectric film disposed above the silicon film, and a conductive layer disposed above the interpoly dielectric film.

6. The device according to claim 5, wherein two or more electrodes being divided by an element isolation film are disposed to provide two or more capacitive elements, and wherein the interpoly dielectric film and the conductive layer extend continuously so as to cover the upper surfaces of the silicon film and the element isolation film, and wherein a via contact is disposed above an end portion of the conductive layer.

7. A nonvolatile semiconductor storage device comprising:
a memory-cell region;
a peripheral-circuit region disposed adjacent to the memory-cell region;
a first memory-cell unit disposed in a first layer located in the memory-cell region;
a second memory-cell unit disposed in a k-th layer located in the memory-cell region where k is an integer equal to or greater than 2, the second memory-cell unit having an element region extending in a first direction and having a first width in a second direction crossing the first direction;
peripheral-circuit elements disposed in the first layer located in the peripheral-circuit region;
dummy elements disposed in the k-th layer located in the peripheral-circuit region so as to extend in the first direction and be spaced from one another by a second width in the second direction; and
contacts contacting the dummy elements via insulating films and extending, in a direction in which layers are stacked, to reach the peripheral-circuit elements in the first layer.

8. The device according to claim 7, wherein the dummy elements located between the contacts are divided from each other.

9. The device according to claim 7, wherein one of the peripheral-circuit elements is a high-breakdown-voltage transistor.

10. The device according to claim 7, wherein the length in the second direction of contacts is greater than the second width.

11. A nonvolatile semiconductor storage device comprising:
a semiconductor substrate;
an element region disposed along a first direction;
negative type impurity doped layer formed continuously in an upper portion of the element region;
memory-cell gate electrodes disposed above the continuous n type impurity doped layers, the memory-cell gate electrodes being spaced from one another in the first direction; and
trenches disposed in both sides of the memory-cell gate electrodes so as to be located in the upper portion of the negative type impurity doped layer of the element region.

12. The device according to claim 11, wherein a gap is provided between the memory-cell gate electrodes and a lower end of the gap is located in at least one of the trenches of the element region.

13. The device according to claim 11, wherein an interlayer insulating film is filled between the memory-cell gate electrodes.

14. The device according to claim 11, further comprising one or more layers of element regions provided above the semiconductor substrate, wherein the one or more layers of element regions are disposed in a second layer or higher layers located above the semiconductor substrate.

15. The device according to claim 11, wherein the trenches in the negative type impurity doped layer of the element region have a depth equal to or greater than 5 nm.

16. The device according to claim 11, further comprising, a silicon-on-insulator disposed between the element region and a positive type layer, and wherein the continuous negative type impurity doped layer is disposed in the element region so as to extend from an upper surface to a lower surface of the element region.
